(19) United States
(12) Patent Application Publication
(10) Pub. No.: US 2012/0105370 A1
(43) Pub. Date: May 3, 2012

(54) Electroded Sheet for a Multitude of Products

(75) Inventor: Chad B. Moore, Corning, NY (US)

(73) Assignee: NUPIX, LLC, Corning, NY (US)

(21) Appl. No.: 13/336,093

(22) Filed: Dec. 23, 2011

Related U.S. Application Data
(63) Continuation-in-part of application No. 12/194,839, filed on Aug. 20, 2008.
Application No. 12/194,839 is a continuation-in-part of application No. PCT/US2006/061872, filed on Dec. 11, 2006.
Application No. PCT/US2006/061872 is a continuation-in-part of application No. 11/609,093, filed on Dec. 11, 2006, now abandoned.
Application No. 11/609,093 is a continuation-in-part of application No. 11/609,131, filed on Dec. 11, 2006, now Pat. No. 8,089,434.
Application No. 11/609,131 is a continuation-in-part of application No. 11/609,220, filed on Dec. 11, 2006, now Pat. No. 8,106,853.
(60) Provisional application No. 61/503,668, filed on Jul. 1, 2011.
(60) Provisional application No. 60/957,317, filed on Aug. 22, 2007.
(60) Provisional application No. 61/060,614, filed on Jun. 11, 2008.
(60) Provisional application No. 60/749,446, filed on Dec. 12, 2005.
(60) Provisional application No. 60/759,704, filed on Jan. 18, 2006.
(60) Provisional application No. 60/827,146, filed on Sep. 27, 2006.
(60) Provisional application No. 60/827,152, filed on Sep. 27, 2006.
(60) Provisional application No. 60/827,170, filed on Sep. 27, 2006.

(51) Int. Cl. G06F 3/045

(52) U.S. Cl. 345/174

(57) ABSTRACT

eSheets create a multitude of different products. One embodiment is a projected capacitive touch sensor created by embedding orthogonal arrays of coated metal wires into the surface of a polymer sheet or onto the back of a projector screen. To increase the capacitance of the electrodes or pixels in the sensor, transparent conductive electrodes can be electrically connected to the wire electrodes. Another embodiment is a reflective, energy-efficient display formed by sandwiching a reflective cholesteric liquid crystal (Ch. LC) material between electroded sheet substrates. The eSheet Ch. LCD is pressure sensitive and can be written on using a finger or stylus. The eSheet Ch. LCD can then be read using the wire electrodes in the eSheet LCD.

### REFERENCE TO RELATED APPLICATIONS

This application claims one or more inventions which were disclosed in Provisional Application No. 61/503,668, filed Jul. 1, 2011, entitled “ELECTRODED SHEET PRODUCTS”. The benefit under 35 USC §119(e) of the U.S. provisional application is hereby claimed, and the aforementioned application is hereby incorporated herein by reference.

This application is also a continuation in part of U.S. application Ser. No. 12/194,839, filed Aug. 20, 2008, entitled “METHOD OF FORMING AN ELECTRODED SHEET”, which claims one or more inventions that were disclosed in Provisional Application No. 60/957,317, filed Aug. 22, 2007, entitled “ELECTRODED SHEET” and Provisional Application No. 61/060,614, filed Jun. 11, 2008, entitled “ELECTRODED SHEET (eSHEET) PRODUCTS” and is a continuation in part of PCT Patent Application Number PCT/US2006/061872, filed Dec. 11, 2006, entitled “WIRE-BASED FLAT PANEL DISPLAYS and abandoned U.S. application Ser. No. 11/609,093, filed Dec. 11, 2006, entitled “TUBULAR PLASMA DISPLAY”.

This application is also a continuation in part of copending U.S. application Ser. No. 11/609,131, filed Dec. 11, 2006, entitled “ELECTRODED POLYMER SUBSTRATE WITH EMBEDDED WIRES FOR AN ELECTRONIC DISPLAY” and copending U.S. application Ser. No. 11/609,220, filed Dec. 11, 2006, entitled “WIRE-BASED FLAT PANEL DISPLAYS”, and PCT Patent Application Number PCT/US2006/061872, filed Dec. 11, 2006, entitled “WIRE-BASED FLAT PANEL DISPLAYS, which all claim one or more inventions that were disclosed in one of the following provisional applications:
1) Provisional Application No. Provisional Application No. 60/749,446, filed Dec. 12, 2005, entitled “ELECTRODE ADDRESSING PLANE IN AN ELECTRONIC DISPLAY”;
2) Provisional Application No. 60/759,704, filed Jan. 18, 2006, entitled “ELECTRODE ADDRESSING PLANE IN AN ELECTRONIC DISPLAY AND PROCESS”;
3) Provisional Application No. 60/827,146, filed Sep. 27, 2006, entitled “TUBULAR PLASMA DISPLAY”;
4) Provisional Application No. 60/827,152, filed Sep. 27, 2006, entitled “ELECTRODED SHEET”; and
5) Provisional Application No. 60/827,170, filed Sep. 27, 2006, entitled “WIRE-BASED FLAT PANEL DISPLAYS”.

The benefit under 35 USC §119(e) of the U.S. provisional applications is hereby claimed, and the aforementioned applications are hereby incorporated herein by reference.

### FIELD OF THE INVENTION

The invention pertains to the field of electronic products, in particular eSheet components to form these products.

### BACKGROUND OF THE INVENTION

Within the electronic display space there is a group of displays that create an image by modulating an electro-optic material. An electro-optic material is defined as a material that changes state in an electric field. Some of these materials can be passively addressed or simply addressed by sandwiching the electro-optic material between two orthogonal arrays of electrodes. However, this passive addressing scheme requires that the electro-optic material has a threshold or its optical properties have an abrupt change over a small change in applied voltage. Most liquid crystal (LC) materials have a steep enough threshold that allows them to be passively addressed. If the electro-optic material does not have a voltage threshold or its threshold is not steep enough (the voltage to totally modulate the material has to be less than twice the voltage of where the material's electro-optic properties start to change), then the electro-optic material has to be actively addressed. Active addressing means that a switch, like a transistor, that has a voltage threshold is used to place the voltage across the electro-optic material. Other active addressing switches that have been used are diodes, plasmas, and micro-electro-mechanical systems (MEMS). Active addressing is also used in cases that require video rate images, because passive addressing requires that a line at a time addressing scheme is used and therefore the speed to update the image is limited to the number of lines in the display times the minimum response time of the electro-optic media.

There are several different types of electro-optic materials. The most well known and widely used electro-optic materials are liquid crystal molecules. In the liquid crystal family, a vast range of molecules could potentially be used to create the electro-optic modulated material. Some of these liquid crystal molecules include, but are not limited to, twisted nematic, cholesteric-nematic, dichroic dye (or guest-host), dynamic scattering mode, smectic, and polymer dispersed molecules. Most of these liquid crystal molecules require other films, such as alignment layers, polarizers, and reflective films.

Another type of electro-optic material is electrophoretic material. Electrophoretic material is a suspension of small charged particles in a liquid solution. If the particles have a similar density as the liquid solution, they are not affected by gravity. Therefore the only way to move the particles is using an electric field. By applying a voltage potential across the electrophoretic solution, the charged particles are forced to move in the suspension to one of the contacts. The opposite charge moves the particles in the other direction. The electrophoretic suspension is designed such that the particles are a different color than the liquid solution or there are two different colored particles with opposite charge states.

Another type of electro-optic material is a twisting ball or Gyricon material. It was initially called twisting ball material because it is composed of small bichromal spheres, one side coated black, the other white, with opposite charges on the two halves. Therefore, when the twisting ball material is placed in an electric field, the bichromal spheres all rotate to display one optical property of the material and when the opposite voltage is applied, the material displays the other colored state. This Gyricon material can also be made in a cylindrical form.

Research Frontiers Incorporated has developed another electro-optic material that they call a suspended particle device (SPD) which consists of microscopic particles in a liquid suspension. These microscopic particles are elongated in one direction and, when randomly orientated, block light. When a voltage is applied across the electro-optic material, the particles align and transmit light.

Most of these electro-optic materials do not have a voltage threshold and must be actively addressed. Some of the liquid crystal materials use an active transistor back plane to address the displays, but these types of displays are presently limited in size due to a complicated and costly manufacturing process. Transmissive displays using liquid crystal materials and a plasma-addressed back plane have been demonstrated in U.S. Pat. No. 4,896,149, herein incorporated by reference; however, these plasma-addressed back planes are also limited in size due to availability of the thin microsheet to create the plasma cells.

One potential solution for producing large size displays is to use fibers/tubes to create the plasma cells. Using tubes to create a plasma-addressable plasma cell was first disclosed in U.S. Pat. No. 3,964,050, herein incorporated by reference. One potential issue in producing large plasma-addressed tubular displays is creating the top column electrode plate. This plate has to be composed of an array of lines to address that set the charge in the plasma tubes. When addressing a thin electro-optic material like a LC or electrophoretic material, these electrode lines have to be wide enough to spread the charge across the width of the entire pixel. The lines also have to be conductive enough to set the charge in the plasma tube so the display can be addressed at video rates. A traditional patterned indium tin oxide (ITO) transparent conductor works fine for smaller panels where processing the panel is easy and the lines are short; however to address very large panels, the ITO lines are not conductive enough and patterning of the lines becomes very expensive.

One method to solve this problem has been proposed in U.S. Pat. No. 7,777,928, “Electrode Enhancements for Fiber-Based Displays”, issued Aug. 17, 2010, and herein incorporated by reference. In that patent, fiber containing an electrode is used to form the column electrode plane. The electrode is composed of a wire electrode, which carries the bulk of the current and a transparent conductive electrode, which is connected to the wire electrode and is used to spread the voltage across the surface of the fiber.

Connecting a higher conductive metal film electrode to a transparent conductive film to spread the voltage of the electrode is also traditionally used in the top electrode plate of a plasma display (PDP). The top PDP plates use a 50 μm wide by about 1 μm thick Cr/Cu/Cr stack to carry current and a thin ITO coating to spread the effect of the voltage, hence spreading the firing of the plasma. These electrode coatings are evaporated or sputtered and then photolithography is used to pattern them and they are then etched into lines using a wet etch or a reactive ion etch (RIE).

Photovoltaic cells also use conductive metal lines connected to transparent conductive coatings to collect the current from the photovoltaic device. The use of wire connected to a transparent conductive coating has been disclosed by Nanosolar in U.S. Pat. Nos. 6,936,761 and 7,022,910, herein incorporated by reference, for solar cell applications.

### SUMMARY OF THE INVENTION

Embodiments of the present invention use eSheets to create a multitude of different products. Electroded sheets and a liquid crystal material create large reflective eSheet LCDs. Methods of creating electrically isolated crisscrossing wire electrodes to form large projected capacitive touch sensors are also disclosed herein. Several new products and markets that presently can not be addressed using the eSheet technology are also disclosed herein. ESheet technology allows products to be manufactured for these market segments.

A projected capacitive touch sensor is created by crisscrossing wire electrodes. The crisscrossing wire electrodes are preferably embedded in a polymer substrate or attached to the surface of a substrate. In order to keep the wires in the crisscrossing wire arrays from shorting out, the wires are preferably coated with an insulating material. One preferred material for the wire is a low-cost, readily available coated metal wire, more preferably a coated copper or other magnetic wire used for winding magnetic motors or transformers. To increase the capacitance of the electrodes or pixels in the touch sensor, transparent conductive electrodes are preferably electrically connected to the wire electrodes. The eSheet touch sensor can be integrated into a multitude of displays. In one embodiment for a potentially very large display, a reflective, energy-efficient display is formed by sandwiching a reflective liquid crystal material between orthogonal eSheet substrates. The wire-based eSheet touch sensor can be combined with the eSheet LCD to form a large interactive energy-efficient display. The display can be covered with a tough glass plate for the interface of the display, for instance, an electronic blackboard. The tough glass is preferably made by ion exchanging thin fusion drawn glass.

Another embodiment is a reflective, energy-efficient display similar to the embodiment explained above, formed by sandwiching a reflective cholesteric liquid crystal (Ch. LC) material between electroded sheet substrates. The eSheet Ch. LCD is preferably pressure sensitive and can be written on using a finger or stylus. The cholesteric liquid crystal material in the eSheet Ch. LCD is preferably bistable and can be written to the focal conical state (transparent/forward scattering state). When the material is disturbed, such as pushing on it with a finger, it changes to a planar texture (reflective state). This change from transparent to reflective state corresponds to a change in the capacitance of the pixel. This change in capacitance can be sensed using the eSheet wire electrodes. Therefore, the entire image on the display can be read after it has been written creating a very efficient display and sensor.

### BRIEF DESCRIPTION OF THE DRAWINGS

FIG. 1 schematically shows an array of wire electrodes electrically connected to transparent conductive lines on a substrate.

FIG. 2 is a schematic representation of an eSheet LCD.

FIG. 3 schematically illustrates a bathtub curve used to determine the addressability of a cholesteric LCD.

FIG. 4 schematically illustrates how a cholesteric LCD can be addressed.

FIG. 5 is a photograph of an addressed 19.2″×19.2″ 10 dpi yellow cholesteric LCD fabricated using orthogonal eSheets.

FIG. 6 is photographs of addressed red, green, and blue cholesteric eSheet LCDs.

FIG. 7 shows photographs of grayscale addressed yellow and blue cholesteric eSheet LCDs.

FIG. 8 is a schematic representation of a color eSheet LCD.

FIG. 9 are photographs of an addressed color cholesteric eSheet LCD.

FIG. 10 is a photograph of a grayscale addressed color cholesteric eSheet LCD.

FIG. 11 is a photograph of an eSheet LCD attached to a fusion drawn glass plate.

FIG. 12 is a photograph of an edge of an eSheet LCD attached to a fusion drawn glass plate.

FIG. 13a is a photograph of a pressure sensitive eSheet Ch. LCD using (a) a yellow cholesteric LC and a black absorbing background.

FIG. 13b is a photograph of a pressure sensitive eSheet Ch. LCD using a yellow cholesteric LC material with a dark blue background.

FIG. 14 schematically shows a cross-section of crisscrossing wire electrodes embedded in a polymer sheet.

FIG. 15 is a microscope photograph of the crisscrossing wire electrodes embedded in a polymer sheet.

FIG. 16 is a photograph of a 20 dpi array of crisscrossing wire electrodes embedded in a polymer sheet.

FIG. 17 is a microscope photograph of the crisscrossing wire electrodes embedded in a polymer sheet, where the surface of the wired sheet has been sanded to expose the wire electrodes.

FIG. 18 is a photograph of an eSheet touch sensor with transparent conductive electrodes patterned on embedded wire electrodes.

FIG. 19 is a photograph of an eSheet touch sensor with transparent conductive electrodes patterned on embedded wire electrodes outlining the vertical and horizontal electrode lines.

FIG. 20 is a photograph of an eSheet touch sensor with transparent conductive electrodes patterned on embedded wire electrodes showing the wire electrodes extending out of the edge of the touch sensor.

FIG. 21 schematically shows a crisscrossing wire touch sensor, where one set of the wire electrodes are connected to transparent conductive electrodes.

FIG. 22 schematically shows a crisscrossing wire eSheet substrate with attached plasma spheres or plasma pucks.

FIG. 23a is an image of Gyricon ePaper switched between two eSheets.

FIG. 23b is an image of E-Ink's electrophoretic material switched between two eSheets.

FIG. 24a is an image of a reflective bistable plasma-addressed display constructed using an eSheet for the column electrode plane.

FIG. 24b is an image of the insides of the plasma-addressed display of FIG. 24a showing all the electrodes being attached to the drive electronics on one edge.

FIG. 25a is an image of an array of plasma tubes connected to an eSheet to form the panel structure in a tubular plasma display.

FIG. 25b is an image of an array of plasma tubes with a red, green and blue color filter coating connected to an eSheet on one side of the tube array to form a tubular plasma display panel and demonstrating that the tube array can be rolled.

FIG. 25c is a photograph of an image on a tubular plasma display.

FIG. 25d is a photograph of an image on a tubular plasma display.

### DESCRIPTION OF THE PREFERRED EMBODIMENT

A sheet in an electronic display includes a substrate containing an array of wire electrodes. The wire electrodes are preferably electrically connected to patterned transparent conductive electrode lines. A second array of wire electrodes preferably crisscrosses the first array of wire electrodes but is electrically isolated from the first array. The wire electrodes are used to carry the bulk of the current. The wires are preferably formed using a standard wire forming process; they are free standing entities and are not evaporated or deposited on the substrate. The wire electrodes are capable of being extended away from the substrate and connected directly to a printed circuit board.

A transparent conductive electrode (TCE) is used to spread the charge or voltage from the wire electrode across the pixel. The TCE is a patterned film and, in most display applications, must be at least 50% transparent, and is preferably over 90% transparent. The TCE is preferably composed of a transparent conductive polymer, nanotubes, or a PVD material like ITO. The TCE must form a good electrical connection with the wire electrode (low interface resistance) and must be electrically connected to the wire electrode along most of the length of the electrode. The TCE material does not have to have a high conductivity, because it only needs to be conductive enough to spread the charge or voltage across the pixel width. The substrate that houses the wires/TCE stripes is preferably made of polymer, silicone, or glass. Use of a thin polymer or silicone substrate yields a light, flexible, rugged sheet that can be curved, bent or rolled.

In order for the electroded sheet (eSheet) to be used in most display applications, the electroded surface is preferably flattened. The electroded sheet may be used as an addressing plane in a passive or actively addressed display. Alternatively, it may be used as a sustainer layer or column addressing layer in a tubular plasma display. The electroded sheet may be used to capacitively address an electro-optic material or capacitively set-up the charge in a panel. The electroded layer may also be used as current carrying stripes to address materials such as electrochromic materials or organic light emitting materials. An electroded sheet can supply power to a line or plane in a device, including, but not limitied to, a display, an eSign, a lamp, a touch screen, a battery, a printer, a speaker, a heater, a sensor, a ribbon cable, or a transmitter. An eSheet can also remove power from a line or plane in a device, such as a solar cell, fuel cell, battery, EMF/EMI shielding, sensor, or antenna.

Electroded sheet (eSheet) technology allows for the manufacturing of very large, low cost, flexible substrates with wire-based electrodes, which can be used to manufacture a multitude of different display components, including large, reflective, bistable, passively-addressed LCDs and large projected capacitive touch sensors. The electroded sheets are primarily composed of thin flexible (rollable) polymer substrates with embedded wire electrodes, which are electrically connected to patterned transparent conductive stripes. The wires are used to carry the bulk of the current along the length of the display and the transparent conductive coating is used to spread the voltage across the surface or line of pixels in the display. The most energy efficient, lowest cost display product to manufacture with these electroded sheets is a reflective bistable passively-addressed display, where a liquid crystal (LC) material is simply sandwiched between two electroded substrates. Images can be placed on the passive-addressed liquid crystal display (LCD) by applying the correct voltages to the sets of wire electrodes in the two orthogonal electroded substrates. When fabricating large passive LCDs, it is imperative to have metal conductors connected to the transparent conductive electrodes in order to get a uniform image, to achieve fast addressing speed, and to eliminate addressing problems. Electroded sheet technology provides a low cost method of manufacturing these substrates and a process scalable to very large sizes.

With the increase in energy costs and the big green push to energy-efficient devices there is interest in saving energy in all devices. One display device that has eluded the general consumer is a large reflective energy-efficient display. There have been some inroads into smaller energy-efficient displays, such as electrophoretic displays for electronic reader books. However, no one has developed a large size energy-efficient reflective display. The main reason for this lack of product is two fold. No one, until the development of the electroded sheet, has solved the highly conductive line issue to overcome the RC time constant when addressing displays. The second limitation is to be able to make the large reflective bistable display in a low cost manufacturing process. The eSheet technology solves both of these issues and ushers in a whole new range of new large display products.

There is starting to be a shift to using electronic displays in school systems around the globe. Schools across the country are preparing for the switch to digital teaching. Electronic books are coming of age and soon all students will be doing most, if not all, of their work electronically. Electronic reader books are gaining traction and tablet or iPad computers are gaining in popularity. Most if not all the technology for the students to switch to electronic tablet and do away with their heavy textbooks is presently available. However, in order to truly switch to electronic teaching, an energy-efficient, long-lasting blackboard solution is required. An electronic blackboard requires a tough glass interface, a touch sensor, and an energy-efficient reflective display. All of these have to be made in a large format for low cost.

### Electroded Sheet (eSheet)

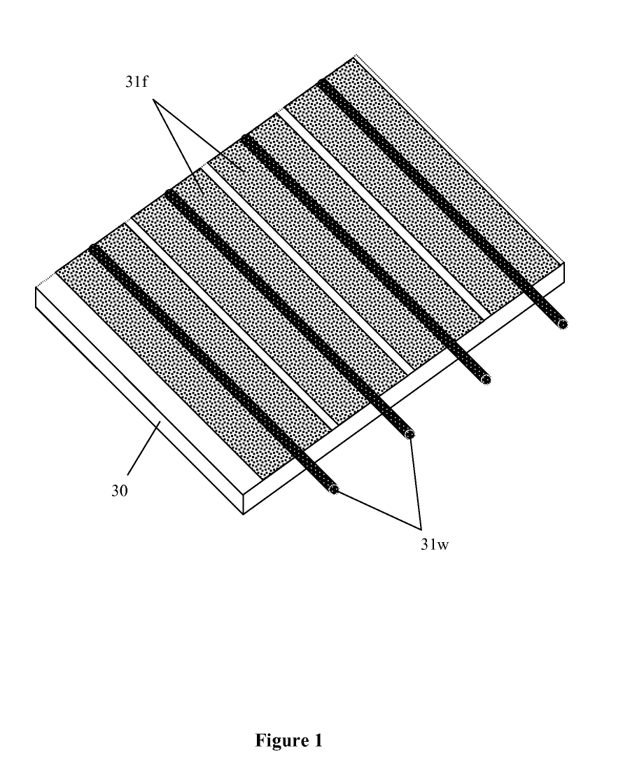

An electroded sheet or eSheet is composed of a substrate 30 containing an array of wire electrodes 31w electrically connected to patterned transparent conductive electrode 31f lines, as shown in FIG. 1. The substrate 30 is preferably made out of polymer and a length and a width of the polymer substrate preferably covers substantially a length and width of the electronic display. The wire electrodes 31w, which are defined as a highly conductive thread-like or fiber-like material herein, are used to carry the bulk of the current along the length of the lines in the eSheet. The wires are formed using a standard wire forming process; they are free standing entities and are not evaporated or deposited on the substrate. The wire electrodes 31w are capable of being extended away from the substrate 30 and connected directly to a printed circuit board. The transparent conductive electrode (TCE) 31f is used to spread the charge or voltage from the wire electrode 31w across a pixel or row of pixels. The TCE 31f is a patterned film that, in most display applications, must be at least 50% transparent, and is preferably over 90% transparent. The TCE 31f must form good electrical connection with the wire electrode 31w (low interface resistance) and must be electrically connected to the wire electrode 31w along most of the length of the electrode. The TCE material does not have to have a high conductivity because it only needs to be conductive enough to spread the charge or voltage across the pixel width. Therefore, the TCE material can be very thin and highly transparent. The substrate 30 that houses the wires/TCEs stripes is preferably made of polymer, silicone or glass. Use of a thin polymer or silicone substrate 30 yields a light, flexible, rugged eSheet that may be curved, bent or rolled.

Using a wire combined with a TCE to form the electrode stripes allows for very high speed addressing of a very large display. The wire electrode, which is used to carry the bulk of the current along the length of the line, has a low resistive drop because it can be composed of a highly conductive material, like copper, and also has a large cross-sectional area compared to a metal film electrode (R=ρ1/A). In order to get a metal film electrode with a low resistivity, the metal has to be deposited using a physical vapor deposition (PVD) process like e-beam evaporation or sputtering, then patterned and etched, which is very costly. Reasonable conductivity may be alternatively achieved using a screen printed silver paste; however, the silver paste has to be fired at elevated temperatures (˜400° C.) to achieve any real conductivity, which is much too high a temperature for most polymers. Most metal conductive coatings that may be economically applied to polymer substrates have only slightly better conductivity (˜5 Ω/□) compared to the most conductive ITO films (˜10 Ω/□).

Controlling the addressing of a large display requires that the voltages applied to the electrodes be uniformly brought up to voltage along the entire length of the line especially if grayscale addressing is required. The lines have resistance along their length and are capacitively coupled to the orthogonal electrodes. The time for the far end of the line to come up to 98% of the total voltage is τ=4 RC. Assuming a 3′×6′ display at 20 dpi is used to address a 5 μm thick liquid crystal with an average dielectric constant of 15, then the total line capacitance is 62 nF. If the line is formed using a highly conductive transparent material with a sheet resistance of 100 Ω/□ then the resistance of the entire line would be 144 kΩ and the line would take 8.9 ms to come up to 98% of the total voltage. If a 0.002″ diameter copper wire is used to carry the current along the length of the electrode, the line resistance would be reduced to 15 Ω and take less than 1 μs to come up to voltage.

The wire electrode may be composed of any composition; however using a low resistivity base material yields the most conductive wire. One potential issue with a highly reflective colored material like copper is that it changes the color of the electroded layer. One method of removing this reflective copper color is to coat the wire electrode with a black absorbing film. This black absorbing layer has to be electrically conductive if it needs to make electrical connection to the transparent conductive electrode (TCE) stripes. The wire coating can be tailored to lower the junction resistance between the wire electrode and TCE. Adding carbon nanotubes to the wire electrode helps lower the junction resistance and make an electrically stronger junction. The TCE is preferably composed of one or more of many different materials including, but not limited to, 1) a conductive polymer, for example Clevios™ conductive polymers (Heraeus, Germany) or AGFA called Orgacon™ electronic materials (AGFA, Belgium), which also goes by the names of Poly(3,4-ethylenedioxythiophene) poly(styrenesulfonate) or [—CH₂CH(C₆H₄SO₃H)—]ₘ[—CH₂CH(C₆H₄SO₃)—_{0.33n}/[C₆H₄O₂S—]^{0.33+} n or PEDT/PSS or PEDOT/PSS; 2) a nanotube or nanorod coating, such as composed of a single wall carbon nanotube or multiwall carbon nanotubes; or 3) a physical vapor deposited (PVD) film, such as indium tin oxide (ITO) or zinc oxide doped with fluorine (ZnO:F). There are many different types of TCE films that may be used. The above films are listed as examples only and are not intended to be an exclusive listing of all the different TCE films.

There are many different methods of applying the TCE coatings. The TCE coatings may be sprayed using a traditional spraying system, however, for some of the TCE coatings, like the nanotube solutions, it would be advantageous to use an ultrasonic sprayer to help break the nanotubes apart as they are sprayed. The TCE coating may also be sprayed using an airbrush, which is useful in that its spray opening may be very well controlled to only let small particles through, hence controlling any agglomerates. Alternatively, the TCE coatings may be printed, which would allow for a low cost method of patterning the lines. Some examples of the printing process include, but are not limited to, transfer printing, screen printing, inkjet printing, slip coating, and intaglio printing. If a TCE slurry solution is used, then the TCE coating may alternatively be brush coated, dip-coated, spin-coated, or extruded. If the TCE coating is a hard coating, like ITO, then a physical vapor deposition (PVD) process is required, for example processes including, but not limited to, e-beam evaporation, sputtering, CVD, and arc spraying.

The TCE coating has to be patterned into lines to electrically isolate one wire with TCE from its adjacent electrode. If a precision printing process is used, then the TCE coating may be easily patterned during the deposition process. If a directional coating process like spraying or some of the PVD processes is used to deposit the TCE film, then a shadow mask may be used to pattern the TCE film into lines. The TCE coating may alternatively be patterned by applying an additional patterned coating, like photoresist, to protect the TCE during an etching process. The patterning and etching process may use several different masking films and methods of applying the masking films and may use a wet or dry etching process to pattern the TCE into lines. The TCE coating may alternatively be patterned into lines using a lift-off process, where prepattern lines are placed on the substrate at the points where the TCE is to be separated. Then, after the TCE film is deposited, the prepatterned lines are removed separating the TCE film into lines. The prepatterned lines may be a polymer, like photoresist, or hard lines like wire, fiber or thread that is removed once coated, which is very similar to a shadow mask. The TCE film may alternatively be cut into lines using a scraping tool or cut with a laser. The TCE film could also be cut by forcing wedge shaped line objects down into the coating. Adjacent TCE coatings may alternatively be electrically isolated by coating the film along the separation lines with a material that reacts with the TCE to destroy the conductive nature of the film. The conductive nature of the TCE film may also be destroyed using heat from a laser beam. There are many different methods of depositing a patterned transparent conductive electrode (TCE); the above methods are listed as examples only and are not intended to be an exclusive listing of all the different coating and patterning methods.

### Reflective Bistable eSheet LCD

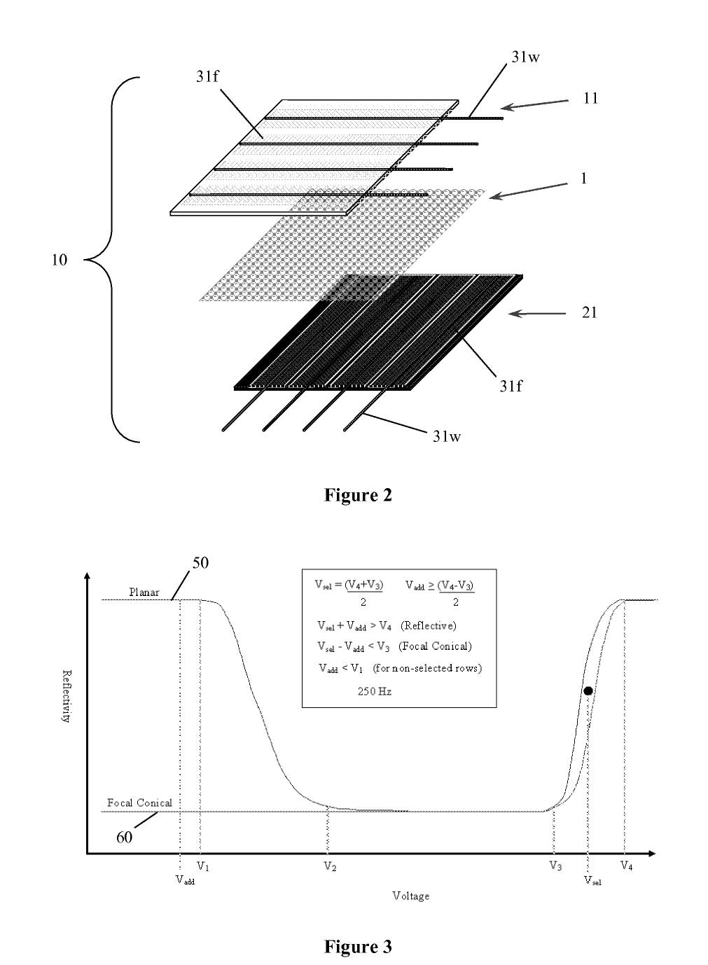

FIG. 2 shows a representation of how eSheet substrates (shown in FIG. 1) can be used to create a reflective bistable liquid crystal display (LCD) 10. A liquid crystal material 1, preferably a cholesteric liquid crystal, switches between transparent and reflective states. The liquid crystal material 1 is sandwiched between two orthogonal electroded sheets (eSheet) 11 and 21. The top eSheet 11 has an array of combined wire 31w and transparent film 31f electrodes on its bottom and is preferably manufactured to be as transparent as possible since the ambient reflected light has to pass through this top eSheet twice. The bottom eSheet 21, which has an array of combined wire 31w and transparent film 31f electrodes on top, should be black and absorbing to absorb any incident light that is not reflected by the liquid crystal material. The display 10 is passively addressed by applying the correct voltage waveforms to the individual wire electrodes 31w to generate an image in the display 10. Addressing a passive display 10 requires that the image is written to the display 10 one line at a time and the electro-optic material has a voltage threshold. The voltage threshold requirement means that the difference in the voltage to switch the display pixel between its two states has to be less than the onset of the switching voltage of the electro-optic material. The cholesteric liquid crystal material 1 can be passively addressed and uses Bragg reflection to reflect circularly polarized light; therefore it does not require a backlight. The cholesteric liquid crystal material 1 is also bistable, which means that when the liquid crystal is modulated to a different state, it holds that state until it is forced back to its original state.

A ‘bathtub’ curve, shown in FIG. 3, is used to measure the multiplexing capabilities of a cholesteric LC cell. Cholesteric LC displays have two bistable states: 1) a planar state 50, where the centerline of the twist in the helix structure is normal to the plane of the substrate and the cell appears reflective, and 2) a focal conical state 60, where the centerline of the twist in the helix structure is in the plane of the substrate and the cell is transparent (or forward scattering). As one can see from the ‘bathtub’ curve, the display can be in a planar (reflective) state or a focal conic (transparent) state at ground potential. As the voltage is increased past V₁ the Ch. LC cell starts to switch to the focal conical state. Applied voltages between V₂ to V₃ switch the cell to the focal conical state irrespective of the initial state. Above V₃ the cell starts to switch to a planar homotropic metastable state (which is actually very transparent) when the AC voltage is applied. Note the curves in the ‘bathtub’ curve in FIG. 3 represent the final state of the display once the voltage is removed. Upon removing the electric field, the cell relaxes to the planar state (once above V₄). Therefore, to address the display a voltage is applied to a row electrode equal to Vₛₑ₁ (where Vₛₑ₁ is midway between V₃ and V₄) then by applying an addressing voltage ±V_{add} to the column electrode (where V_{add} is greater than [(V₄+V₃)/2)] the cell can be switched between the focal conical or planar state. In order for the non-selected rows not to be altered by the column addressing voltage, it (V_{add}) must be lower than V₁ or the onset of a change from the planar state to the focal conical state. Thus, if all the conditions in the box are met then the display can be multiplex addressed.

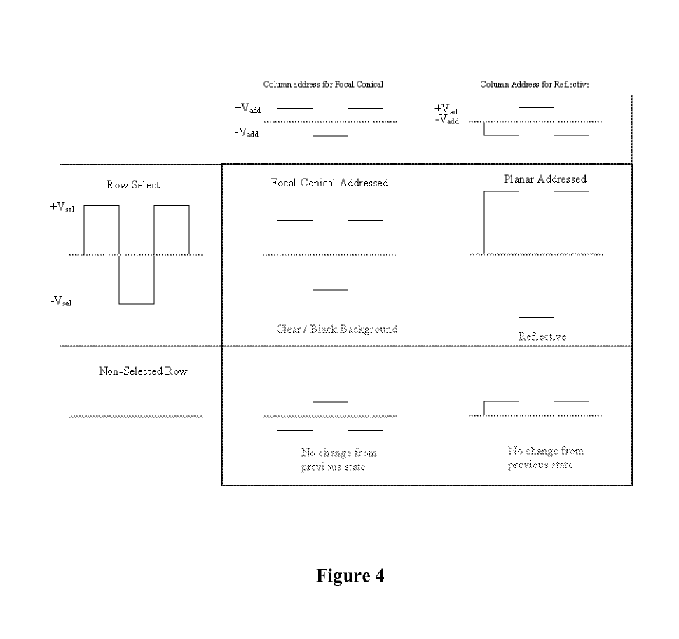

FIG. 4 shows an example of how the display can be multiplex addressed. The column on the left shows the row voltages applied to each row in the display. The top row shows the column voltages applied to each column in the display. The voltage or electric field across each pixel in the display is equal to the row voltage minus the column voltage. Therefore, in the selected row the first cell experiences a voltage equal to ±(Vₛₑ₁−V_{add}) and switches to the focal conical or transparent state, whereas, the second cell in the selected row experiences a voltage equal to ±(Vₛₑ₁±V_{add}) and switches to the reflective planar state (once the next row is selected and the total voltage is reduced to V_{add}). The non-selected rows only experience ±V_{add} and are not affected by the column voltages.

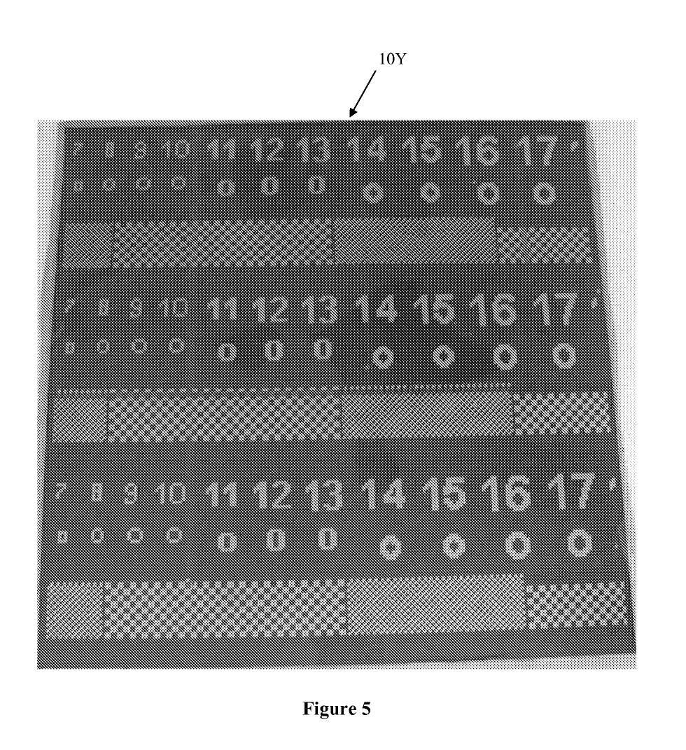

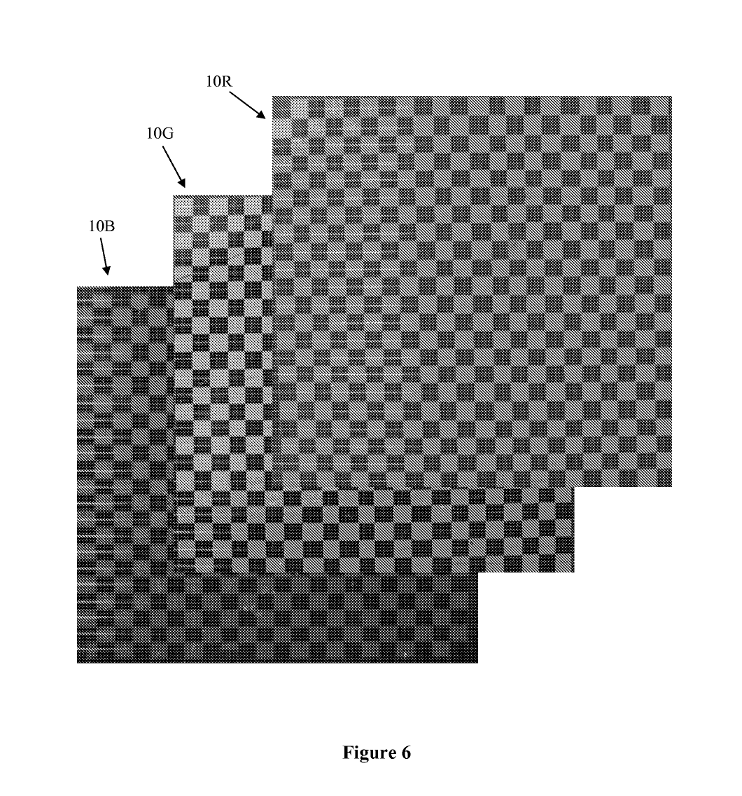

FIG. 5 shows a reflective bistable cholesteric liquid crystal display 10Y formed by sandwiching a yellow cholesteric liquid crystal material between orthogonal eSheets. The eSheet electrode pitch is 10 lines per inch (dpi) and there are 192×192 pixels in the display. The wires connected to transparent conductive electrode stripes easily address the 20 inch long electrode lines. The display used a reflective yellow cholesteric liquid crystal material; however the pitch of the chiral molecule in the liquid crystal can be tailored to reflect any color. FIG. 6 shows that the cholesteric liquid crystal material can be formulated to make cholesteric LCDs that reflect red 10R, green 10G or blue 10B light. The cholesteric liquid crystal materials Bragg reflect a narrow color band of circularly polarized light and allow all other colors to transmit through.

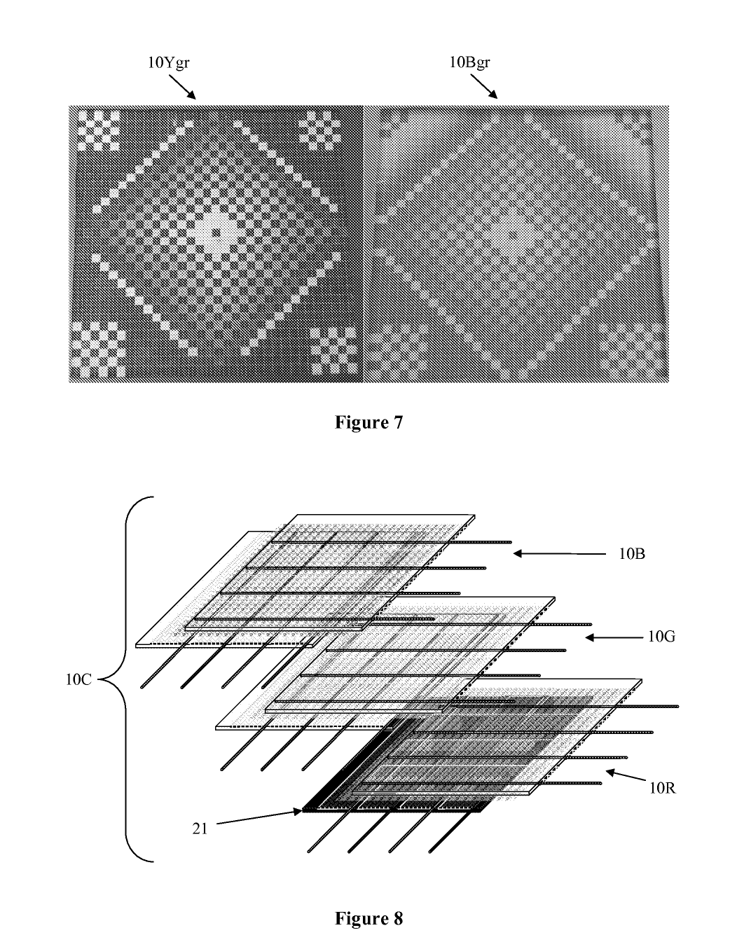

The eSheet Ch. LCD can be grayscale addressed as shown in FIG. 7. FIG. 7 shows both a Yellow 10Ygr and a Blue 10Bgr cholesteric LCD being grayscale addressed using 8 different levels of reflectivity within the LCDs. Grayscale addressing can be achieved by several different methods. The amount of the planar or focal conic texture at each pixel is controlled by the voltage and somewhat by the time at that voltage in two different addressing regions. First the data voltage can be controlled during the standard addressing discussed above to choose a point along the curve between V₃ and V₄ in the ‘bathtub’ curve, shown in FIG. 3. Controlling the analog data voltages selects the amount of planar or focal conic texture at each pixel. The slope in the ‘bathtub’ curve between V₁ and V₂ can also be used to set the grayscale at each pixel in the display. However, in this case the pixel must start in the planar state and increasing the voltage drives the pixel toward the focal conic texture.

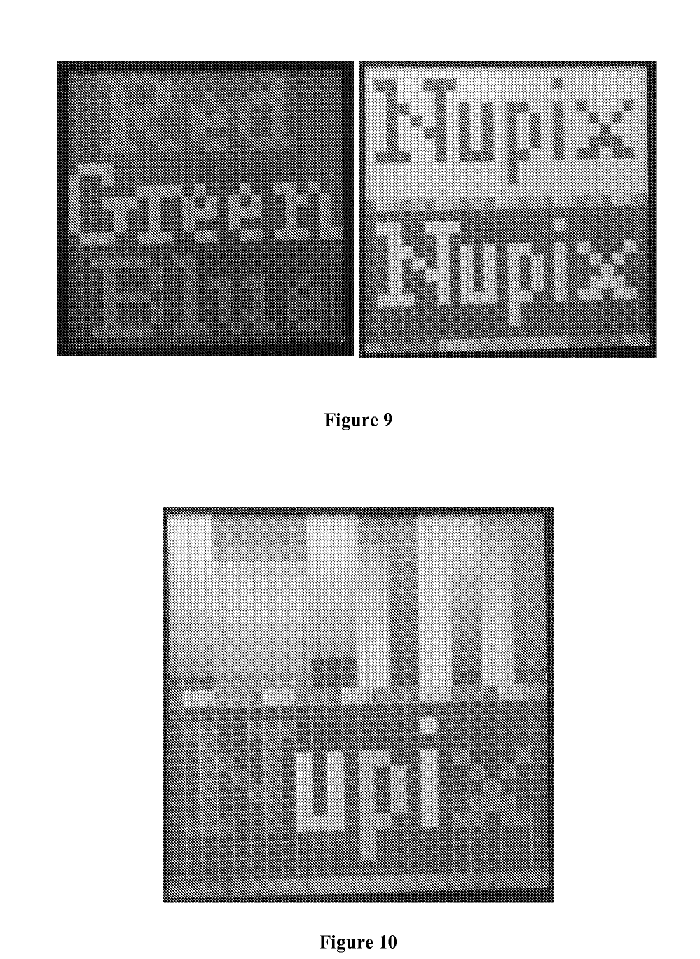

Traditional liquid crystal displays use 3-4 different color cells per pixel only allowing each of the primary color to pass through each subpixel to form a single pixel. Using a 3 primary color filter and a reflective liquid crystal material would mean that at most 1/3 of the available light could be reflected back The most effective way to create a reflective color display is by stacking three red 10R, green 10G, and blue 10B color panels, one on top of the next, as shown in FIG. 8. The lower or bottom cholesteric LCD 10R has a black eSheet 21 to absorb any transmitted light transmitting through the three LCD panels (10B,10G,10R) to create black or contrast in the three-layer color stacked LCD 10C. A three-layer color stack LCD 10C is capable of reflecting the entire light incident on the pixel, as opposed to all other color displays that place the three colors side-by-side using a color filter, where ⅔ of the incident light is lost. This stacking method requires that the electro-optic materials are modulated from a transparent state to a reflective red, green or blue state. The Ch. LC materials Bragg reflect a narrow color band of circularly polarized light and allow all other colors to transmit through. To achieve a black image the bottom of the color state is painted black 21. Therefore, creating a reflective color Ch. LCD 10C is as simple as stacking three individually filled red 10R, green 10G, and blue 10B panels one on top of the other, as shown in FIG. 9. These two photographs show a stacked eSheet color Ch. LCD 10C being addressed using 1-bit of grayscale or each pixel in the three primary LCD panels (10B:10G:10R) either being switched to a planar state 50 or a focal conic state 60.

A full color grayscale eSheet LCD 10C (FIG. 10) can be made by grayscale addressing each of the three color panels (10B, 10G, 10R) similar to that done for single monochrome panels discussed above and shown in FIG. 7. The photograph shows each of the three individual color panels (10B,10G,10R) being addressed using 8 shades of gray.

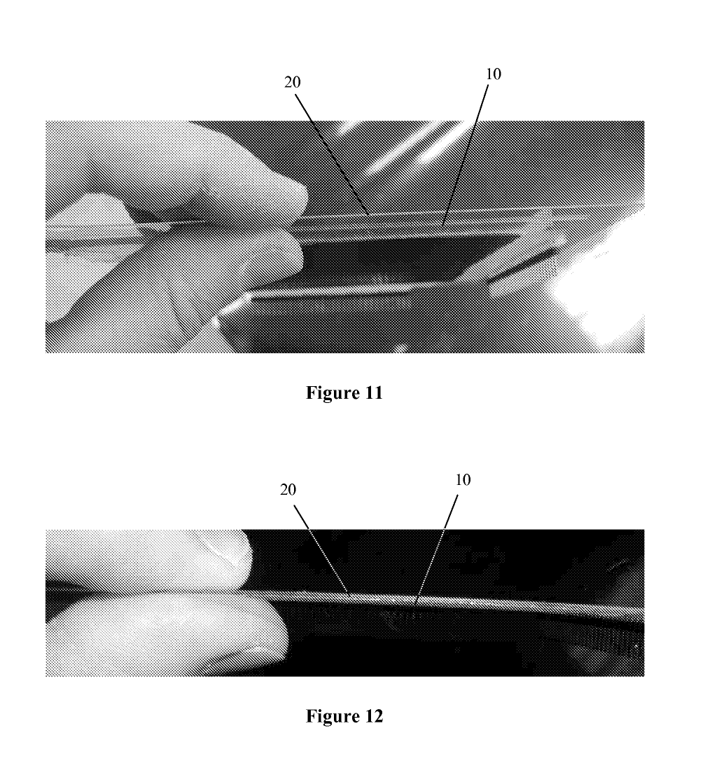

The reflective, bistable, eSheet LCDs 10 can be attached to glass plates 20 to protect the polymer eSheet substrate from damage, as shown in FIG. 11 (a tilted view) and FIG. 12 (a direct edge view). Contact adhesive was used to attach the polymer-based eSheet LCD 10 to a sheet of thin fusion drawn glass 20. The fusion drawn glass 20 is only 0.02″ (0.5 mm) thick. This thin fusion drawn glass 20 can be made in an ion exchanged form therefore creating a very tough, thin, light weight, full-color, gray-scale, cholesteric liquid crystal display.

### Pressure Sensitive eSheet LCD and Sensor

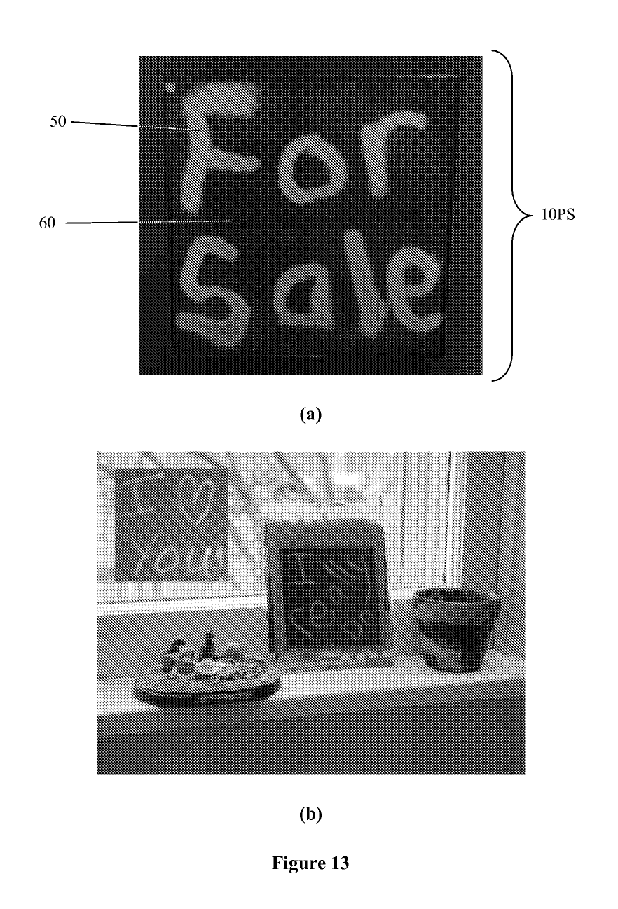

The eSheet LCDs can also be backed with a stiff plate. The plate can be made out of metal, glass, plastic, wood or any other material that supports a stiff flat surface. Bonding the eSheet cholesteric LCD to a plate provides support to the bendable plastic eSheet LCD; therefore when the surface of the eSheet is pressed the force is translated through the eSheet LCD. The force from a solid object, like a finger or stylus, causes sheer in the cholesteric liquid crystal layer. This sheer is caused by the two eSheets coming closer together due to the pressure of the solid object pressing on the surface and the stiff back plate holding the back eSheet flat. When the eSheets come together, the cholesteric LC cell gap is reduced causing the LC to flow. The flowing of the LC sheers the cholesteric LC material. Since the planar state is a lower energy state, the cholesteric LC material switches to this reflective state when the cholesteric LC is physically disturbed. Therefore, by simply writing on the surface of the eSheet Ch. LCD with a finger causes a phase change from the focal conic state 60 to the planar state 50, as shown in FIG. 13. The pressure sensitive eSheet Ch. LCD panel LOPS could also optionally be covered with a thin glass microsheet on the input side of the eSheet Ch. LCD panel LOPS. Making the thin glass cover sheet very thin allows for the deformation to be transferred through the thin glass plate into the Ch. LC layer. The thin glass cover sheet also protects the top plastic eSheet 11 from getting scratched.

The optical difference between the planar state (reflective) and focal conical state (transmissive/forward scattering) in the cholesteric liquid crystal (Ch. LC) materials system leads to a large change in the index of refraction of the two states. This large change in index of refraction is a result of the large change in the dielectric constant of the two states. The dielectric constant, εᵣ, is directly related to the capacitance, C, of the material or the capacitance of the pixel in the display by C=εᵣεₒA/d, where εₒ is the permittivity of free space (8.854×10⁻¹² A·s/(V·M)=8.854×10⁻¹² F/m), A is the area of the pixel and d is the LC cell gap. Therefore, by reading the capacitance of each pixel in the display, the state of that pixel (reflecting or transmitting) can be determined In fact, the amount of each state (planar or focal conic) can be determined by reading the pixel capacitance. Therefore, if the eSheet Ch. LCD is written into the focal conic state (transmissive) and the panel has a black background, then the panel looks dark. The surface of the panel can be written on using a finger similar to that shown in FIG. 13. Using the electrodes in the orthogonal eSheets, the capacitance at each pixel can be measured. An example of this capacitive sensing phase change is a 3.2″×3.2″ 10 dpi panel written to the black (focal conical) state. In this example, all the electrodes on one of the eSheet were tied together and a multimeter on capacitance setting was attached between the ganged up wire electrodes on the one eSheet and a single electrode on the other eSheet. The capacitance was measured to be 4.87 nF. Pressing down on the panel created a phase change to the planar state about ½″ wide along the 0.1″ selected eSheet line. The capacitance decreased to 4.43 nF. Rubbing a finger along the entire line caused the entire line to switch to the reflective (planar) state. The capacitance was measured to be 2.70 nF. This experiment shows that the phase change between the transmitting (focal conic) and reflecting (planar) state can be capacitively measured. It also shows that the dielectric constant of the focal conic (˜18 from the above equation) is about twice that of the planar state (˜9.6). This change between the capacitance of the two states corresponds to a change of about 6.78 nF/sqin.

The pixel capacitance measuring can be done one line at a time, similar to writing the image in the display. A waveform could be placed on the first scan electrode, and all the data electrodes could be used to sense the waveform that is transmitted through the pixel capacitance. The change(s) in the waveform on each data electrode correspond to the pixel capacitance where the data and scan electrodes cross. Using the proper electronics the pixels in the cholesteric LCD can be electronically addressed, and the image on the display can be read. This allows for a display to be addressed with some information and the information to be annotated then the resulting image read. The initial electronically written image can be subtracted from the electronically read image, and the annotation can be determined Note that this display can be very energy efficient. The image in the electronically writable part of the display is reflective and bistable, thus requiring no power to display the image. The display is also pressure sensitive; thus the display can be written on with a stylus or finger requiring no electronic power. Finally the display can be read after it has been electronically and mechanically written on to electronically acquire the image.

### eSheet Projected Capacitive Touch Sensor

An eSheet projected capacitive touch sensor is formed by crisscrossing two arrays of wire electrodes 31wX and 31wY. One method of fabricating an eSheet projected capacitive touch sensor embeds a first array of wires 31wY into a polymer sheet and a second array of wires 31wX into the same polymer sheet over top of the first array of wires 31wY. The second set of wire electrodes 31wX could also be intertwined with the first array of wires 31wY. In another embodiment, the second set of wire electrodes could be embedded in a separate second polymer sheet, and the first and second wire embedded polymer sheets are then sealed or laminated together orthogonal to each other to form a wire-based projected capacitive touch sensor. In order to keep the wire electrodes electrically isolated from each other, at least one of the two wire arrays have to be coated with an insulating film or an insulating film has to be placed between the two wire embedded plastic sheets.

Alternatively, an eSheet projected capacitive touch sensor is fabricated by embedding a first array of wires 31wY into a polymer sheet and a second array of wires 31wX preferably orthogonal to the first array of wires and over top of the first wire array into the same polymer sheet. At least the first set of wire electrodes have to be made out of a soft metal so they can plastically deform when the second set is pushed into the surface of the polymer sheet. In a preferred embodiment, magnet wire is used for the wire electrodes. Magnet wire or enameled copper wire is a copper or aluminum wire covered with thin insulation. The wire itself is most often fully annealed, electrolytically refined copper. Aluminum magnet wire has lower electrical conductivity; an aluminum wire must have 1.6 times the cross-sectional area as a copper wire to achieve comparable DC resistance. Modern magnet wire typically uses one to three layers of polymer film insulation, often of two different compositions, to provide a tough, continuous insulating layer. Magnet wire insulating films use (in order of increasing temperature range) polyurethane, polyamide, polyester, polyester-polyimide, polyamide-polyimide (or amide-imide), and polyimide. Polyimide insulated magnet wire is capable of operation at up to 250° C.

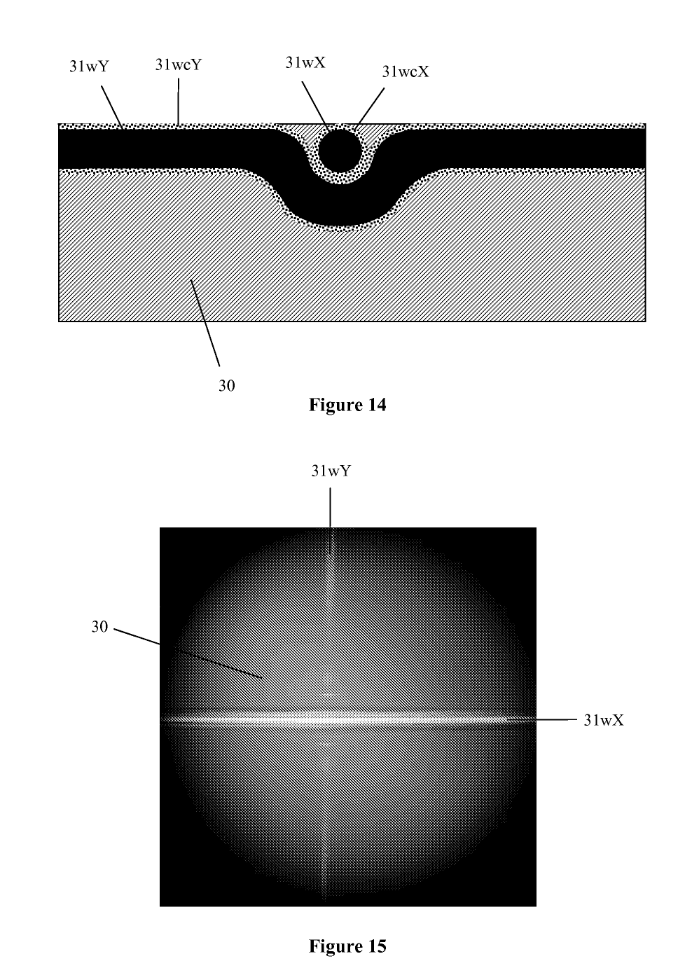

FIG. 14 shows a sketch of a cross-sectional view of how the bottom wire 31wY bends around the top wire 31wX when they are embedded into the polymer substrate 30. Notice that the coatings 31wcX and 31wcY keep the wire electrodes 31wX and 31wY electrically isolated from each other. FIG. 15 shows a microscope view of two orthogonal wire electrodes 31wX and 31wY embedded into the surface of a polymer substrate 30. Note how the vertical wire 31wY disappears from view as it goes underneath the horizontal wire 31wX. Profilometer scans show that the surface roughness or wire protrusion is less than 1 μm across the surface of the embedded polymer sheet.

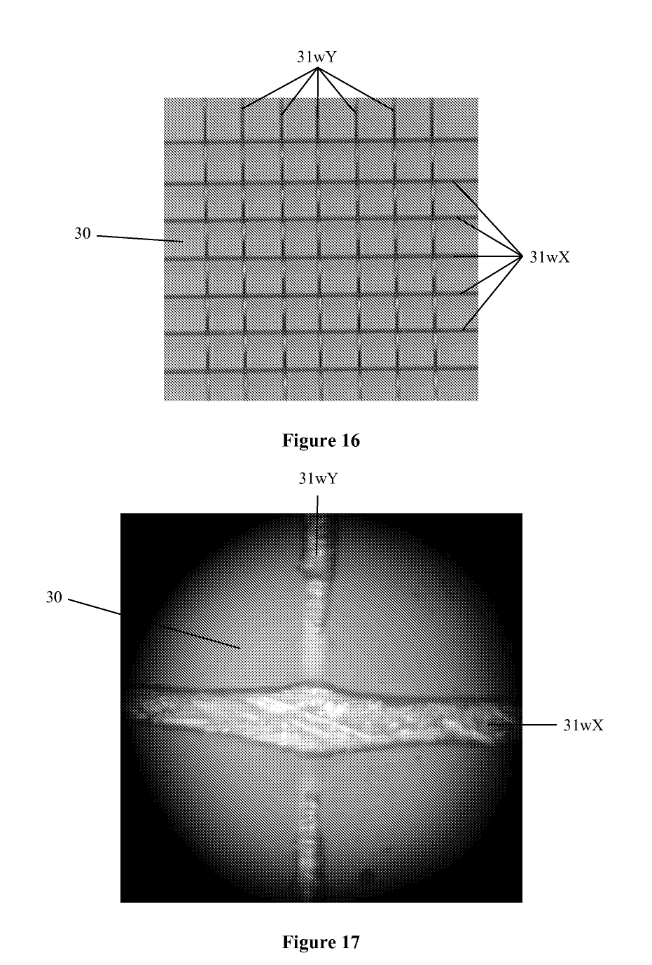

FIG. 16 shows a photograph of the surface of two orthogonal arrays of coated copper wires 31w embedded into the surface of a polymer substrate 30. The coated copper wire is preferably similar to magnetic wire used in transformers or motors. The coated copper wire is 0.0057″ in diameter and the wire is on a 20 lines per inch pitch or spaced on a 0.05″ pitch. The >5 mil diameter copper wire can be embedded into the surface of the polymer substrate and the bottom wire can plastically deform enough such that both wire arrays are even with the polymer surface between the crossing wire junctions. Although the coated wire electrodes 31wX and 31wY in FIG. 16 is large (0.0057″ diameter), a much finer coated copper wire, down to less than 0.0005″ diameter (½ mil or 12 μm diameter), can be used; therefore the metal grid would not be visible by the naked eye. The reflection from the copper wire can be changed or reduced by dying the insulating polymer layer on the wire. The polymer coating can be dyed any color to create a specific reflection or dyed black to blend into the background.

Pressing the wires into a polymer sheet controls the exact pitch and spacing of the wire and makes the surface of the wired electroded sheet very flat. All the wires in the exact same plane would create a very uniform sensor across the entire large sheet. The flat wire eSheet PCT sensor can be laminated to the back of a glass plate without creating any air gaps that cause reflections.

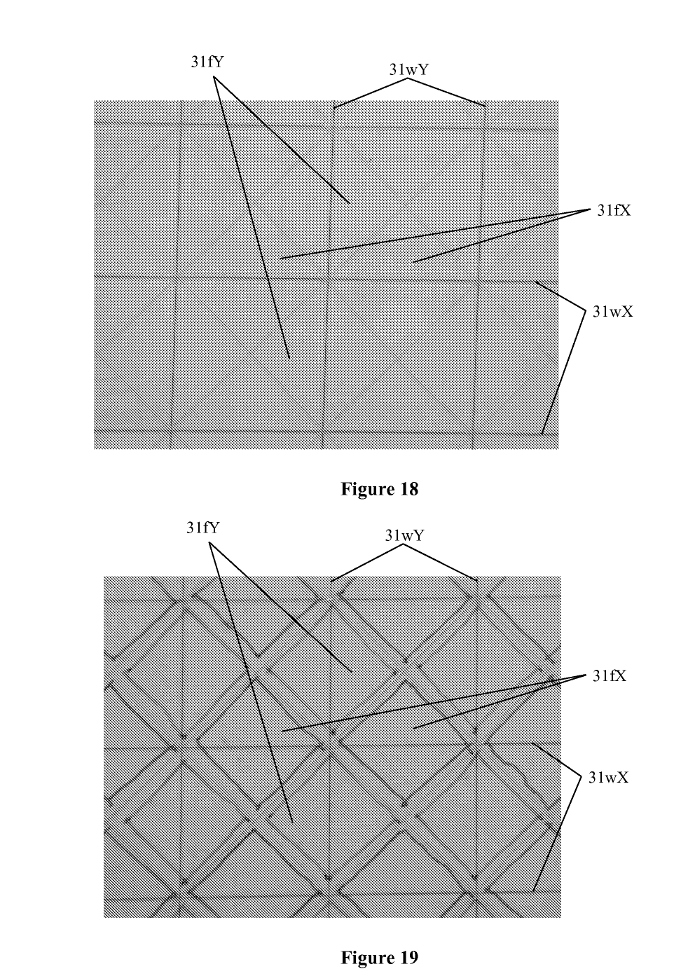

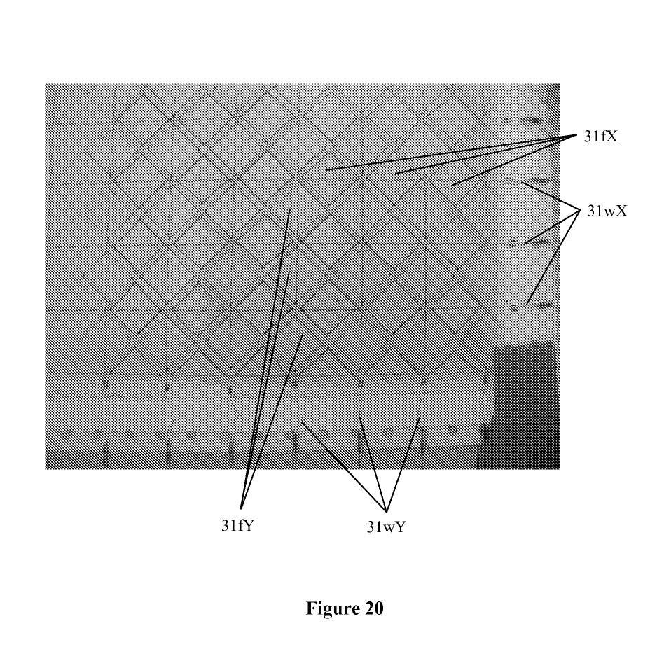

The orthogonal arrays of embedded wire electrodes can be used to sense the location of the touch on the panel surface by sensing the projected capacitance or change in capacitive loading at each wire line. To increase the sensitivity of the projected capacitive touch sensor, transparent conductive electrode pads or stripes can be electrically connected to the wire electrodes to increase the capacitance of the lines or the effective capacitance at every point in the sensor. In order for a transparent conductive coating to be attached to the wire electrodes, the insulating wire coating 31wcX and 31wcY needs to be removed from the wire electrodes 31wX and 31wY at the electroded sheet surface. This coating could be chemically or laser etched off or mechanically removed by sanding. FIG. 17 shows a microscope image, where the surface of the embedded wire eSheet was sanded to remove the isolation coating on the wire electrode. Notice that mechanically sanding the eSheet surface removes the isolation coating from the wire, however does not affect the isolation coating at the wire junction, and the two wire electrodes stay electrically isolated. Since the wire electrodes 31wX and 31wY have been exposed to the surface, the eSheet surface can be coated with a transparent conductive coating and the transparent conductive coating can be electrically connected to the wire electrodes. The transparent conductive electrode 31f can then be patterned to isolate the transparent conductive coating and wire electrodes, as shown in FIG. 18. Note that the wire electrodes run horizontal 31wX and vertical 31wY and the transparent conductive electrode 31fX and 31fY coating is scored at 45° and −45° and cross the wires at the junction. This transparent conductive patterning creates diamond shaped capacitive pads 31fX and 31fY along the wire electrodes, as shown in FIG. 19. The vertical wires 31wY are connected to the ‘green’ pads 31fY and the horizontal wires 31wX are connected to the ‘red’ pads 31fX. FIG. 20 shows a photograph of the edge of the projected capacitive touch sensor showing that the wires 31wX and 31wY can be brought out of the side of the display. These wires 31wX and 31wY can be connected directly to the control and sense electronics.

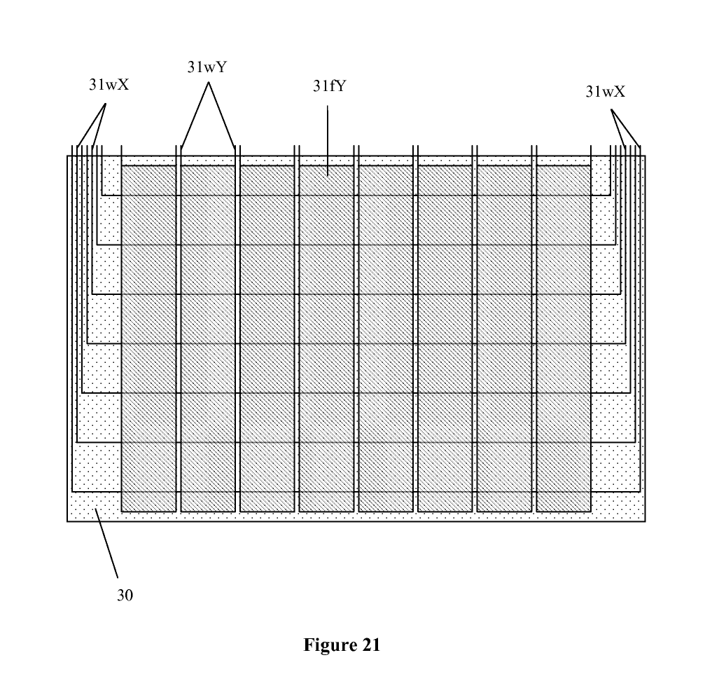

FIG. 21 shows another version of the eSheet projected capacitive touch sensor that uses narrow scan wire electrodes 31wX with wide wire-based data electrodes 31wY and 31fY. The scan electrodes 31wX can be a single wire embedded in a polymer substrate 30. The scan wire electrode 31wX should be coated with a dielectric isolation layer, like magnetic wire. To increase the capacitance of the system, the data electrodes 31wY can be electrically connected to transparent conductive electrode stripes 31fY. Using transparent conductive electrodes allows the touch sensor to be transparent. The data electrodes 31wY could be connected to non-transparent conductive electrode stripes 31fY if the touch sensor was not to be viewed through, such as on the back of a projector screen. Note that the scan electrodes 31wX turn 90° and come out of the top of the display so all the electronics can be connected to one edge of the touch sensor. The data electrodes 31wY plus 31fY substantially cover the entire back side of the touch sensor, which provides the largest capacitive signal.

One method of increasing the capacitance of the wires sands them to roughen up the surface. The roughed up surface has a larger surface area. The exposed roughened wires can also be coated with nanotubes, nanorods or whiskers. Applying particles to the wire surface increases the field lines at any sharp points to increase the electric field emitting from the wires. One easy method of applying point emitters sands the magnetic copper wire embedded crisscrossing eSheet wires with single wall carbon nanotubes. The carbon nanotubes get imbedded into the copper wire and serve as point emitters to enhance the electric field along the exposed wires.

FIG. 21 shows a webbed data electrode where the transparent conductive electrode stripes 31fY are connected between a pair of data wire electrodes 31wY. Note that if the touch sensor does not have to be transparent, the webbed electrode stripes 31fY can be composed of a non-transparent conductive material, like a metal coating. One example uses a metal coated polymer sheet and pattern the metal film into electrodes stripes and then attaches or embeds electrically isolated wire electrodes to the surface orthogonal to the patterned metal data electrode stripes. Also, if the touch sensor does not have to be transparent, the entire data electrode 31wY plus 31fY can be a wide metal electrode that is embedded into the polymer or silicone sheet. The wires in the touch sensor could be made out of copper such that they can be easily soldered to a printed circuit board. They could also be composed of a stiffer metal wire like stainless steel or tungsten that would only elastically deform when rolled “up and down”. The wire electrode 31wX could be run up both sides of the back of the touch sensor, like shown in FIG. 21, and be driven from both sides to lower the inductance. Using an interdigitatedly drive scan line balances the capacitive voltage generation from side to side. Interdigitated “scan” electrodes could also provide for a different sensing scheme that would drive and sense the “scan” lines for a vertical touch before spending the time to pinpoint the exact horizontal location using the “data” lines. Interdigitated scan lines 31wX can be created by connecting every other scan line 31wX to the electronics on both sides of the sensor. Wires 31wX running up both sides also balance the stiffness of the touch sensor on both sides when rolling it “up and down”.

The wires 31wX and 31wY can be held onto the back of the substrate 30, which could be a projection screen, using a pressure sensitive adhesive or a thermal adhesive. The “magnetic” wires in the wire arrays could also be coated with a contact or thermal adhesive and the wire arrays could be bonded directly to the back of the projector screen. Bonding the wires directly to the back of a projector screen using an adhesive would remove the requirement for a separate substrate thus creating a more flexible and rollable screen. If the horizontal wires 31wX turn 90 degrees and run up the side of the panel and connect into the electronics then all the electronics can be on one side and can be housed inside the pull-down screen. Additionally a wireless link can be housed inside the pull down housing to communicate to the projector or computer.

The eSheet wire grid projected capacitive touch sensor(s) could be placed behind a rigid non-conductive plate, like a white board. The eSheet wire grid projected capacitive touch sensor(s) could likewise be placed behind a reflective non-conductive projection surface. The projector screen could be rigid or a flexible/rollable fabric. The wire electrodes in the eSheet capacitive touch sensor could be brought out of the sides of the eSheet sensor sheet and turned 90° and both sets of the wires could be connected to the electronics on one edge of the sensor. This wire electrode connection would allow for a truly rollable touch sensor.

If it is not necessary for the wires to be connected to a transparent conductive electrode to increase the panel capacitance, the crisscrossing wire electrodes could be placed directly on the back of a rigid or flexible substrate. The wire arrays could be arrayed up on the back of a substrate, such as a projection screen, a tough glass plate, or an electronic whiteboard, and a polymer or silicone coating could be placed over the back side of the touch sensor. One advantageous coating is a pressure sensitive or thermal adhesive on a thin polyethylene terephthalat (PET) or Mylar film. The entire system can be placed in a vacuum bag and the thermal flowable adhesive can bond the wire grid to the back of the substrate. Note that the pressure in the system is required to be below about 200 mTorr to remove all the air bubbles. Also, the adhesive thickness has to be about twice the wire diameter to create a flat back. If the back surface does not have to be flat then enough contact adhesive is need to flow around the wires to hold them onto the back surface. Likewise, the adhesive could be coated directly onto the wire before arrayed and the adhesive coated wire could then be bonded to the substrate. A soft material “cloth” can be placed across the back of the eSheet touch sensor during the vacuum bagging process to conform and press and mold the wires to the back of the touch sensor. Likewise, a rubber or silicone coated roller could be rolled across the back of the eSheet touch sensor surface to mold the wire and the adhesive to bond it to the back of the eSheet sensor. Note that if a thermal sensitive adhesive is used then heat would have to be added during the eSheet touch sensor forming process. If a pressure sensitive adhesive is used, then a vacuum can be drawn in the eSheet sandwich to bond the wires tightly to the back or front of a plate or projection screen. If the vacuum is below about 200 mTorr, then most of the air is removed from around the wires and the wires grid are flat and tightly bonded to the substrate. The wire grid could also be made out of a woven wire grid. The woven wire would have to be attached or embedded into an eSheet substrate to form the eSheet touch sensor.

One method of forming a drapeable touch sensor creates a porous eSheet touch sensor. To accomplish this, one could start with an eSheet substrate that has a matrix array of holes. In order for the capacitive fields to appear uniform, the holes either have to be about 10 holes per wire to randomize out the difference in dielectric constant between the air gap and the polymer substrate, or the wire has to be aligned to the solid polymer sections in the eSheet substrate. Likewise, orthogonal arrays of polymer fibers or plastic strips can be used to form a drapeable eSheet substrate. More than one wire could be used per fiber or plastic strip, but the designer has to make sure the electric field lines are not affected by the air/plastic gaps at the edge that cause a change in dielectric constant, hence change in electric field lines across those edges.

The eSheet touch sensor can be designed with a back conductive layer to act as a “ground plane” and could also be charged to help “push” the EMF field from the scan wire out of the front surface of the touch sensor. A back “ground” plane would help the touch sensor from being sensitive to anything behind the sensor like changes in volume with changing dielectric constants or electric voltages. Being able to push the scanned electric field out of the front of the display would also make it more touch sensitive. The back ground plane could also be a row of wires. The wires could be aligned with the scan wires or be offset or in between the eSheet touch wires.

There are many different structures that can be fabricated using two nominally orthogonal arrays of wire electrodes. Wire electrodes are defined as free standing wires that can be spooled or are spooled on a bobbin. The eSheet touch sensor wires are wrapped as free standing wires onto a surface and attached to the surface using heat, UV, contact adhesive or a polymer or silicone overcoat.

There are many different eSheet structures that can be used from a simple crisscrossing wire grid, to a coated and patterned diamond shape on the wire grid, to multiple parallel wires per scan lines with one or more nominally orthogonal wires per sense lines. The wires could also be attached in a zigzag shape to increase the capacitance or sensing of the touch panel.

### Electronic Blackboard or Whiteboard

One of the embodiments of the present invention is an electronic blackboard or white board. The largest market for this type of product is in schools, where it would replace the school blackboard. The product has three key sections; a tough glass surface, a sensor for input, and a reflective bistable energy efficient display. The reflective bistable energy-efficient display can be manufactured by simply sandwiching a reflective liquid crystal material, like a cholesteric liquid crystal, between two orthogonal electroded sheets. The electroded sheets or eSheets can be formed by embedding wire electrodes into the surface of a polymer sheet and electrically connecting transparent conductive electrode stripes to the wire electrodes. The wire electrodes are used to carry the bulk of the current along the length of the line, and the transparent conductive electrode is used to spread the voltage across the row of pixels. This reflective eSheet liquid crystal (LCD) display can be passively addressed by applying voltages to the wire electrodes in the orthogonal eSheets. Because the wire electrodes can be made very conductive, very large addressable displays can be made. Because the eSheets transparent conductive electrode (TCE) can be made very transparent, the three layered stacked color LCDs can be made to have high reflectivity. The reflective LCD can be attached to the back side of a tough glass plate using contact adhesive to hold the display panel onto the glass and to remove any reflection at that interface. To complete the interactive “smartboard”, a touch sensor is added to the device. One potential interactive touch sensor is a projected capacitive touch sensor fabricated using orthogonal wire arrays embedded into the surface of a polymer substrate. The touch location on the panel can be determined by applying a voltage and sensing the capacitive load on each wire in the XY grid. To increase the capacitance of the wire grid projected capacitive touch sensor, transparent conductive stripes can be patterned onto the wire electrodes. The projective capacitive touch sensor could also be combined with the eSheet LCD, such that the capacitive touch sensor serves at the top addressing electrode plane in an LCD.

The tough glass for the blackboard or whiteboard application is preferably made out of a strained multilayered glass sheet. The tough glass is preferably created by placing the surfaces of the glass sheet under compression and the center under tension. Toughened glass is physically and thermally stronger than regular glass. The greater contraction of the inner layer during manufacturing induces compressive stresses in the surface of the glass balanced by tensile stresses in the body of the glass. For glass to be considered toughened, the compressive stress on the surface of the glass should be a minimum of 69 MPa. For it to be considered safety glass, the surface compressive stress should exceed 100 MPa. The greater the surface stress, the smaller the glass particles will be when broken. It is this compressive stress that gives the toughened glass increased strength. This is because any surface flaws (scratches) tend to be pressed closed by the retained compressive forces, while the core layer remains relatively free of the defects which could cause a crack to begin. The surface compression makes the glass sheet tougher and more resistant to scratches. There are three preferred methods for creating tough strained glass sheets:
1) Temper or thermally cool the glass plates to create a stressed surface,
2) Chemical strengthen or ion exchange the surface of the glass to create a stressed surface, or
3) Laminate three glass sheets together to create a stressed surface.

Tempered glass is made from rapidly cooling the surface of the glass sheet. The glass is placed onto a roller table, taking it through a furnace that heats it above its annealing point of about 720° C. for most glasses. The glass is then rapidly cooled with forced air drafts while the inner portion remains free to flow for a short time. In order for the surface to be quenched while keeping the center still viscous, it is best if the tempered glass is thicker than ⅛″ or greater than 3 mm thick. Therefore, tempered glass is traditionally thick and heavy.

An alternative chemical process involves forcing a surface layer of glass at least 0.1 mm thick into compression by ion exchange of a first set of ions in the glass surface with a second set of larger ions, by immersion of the glass into a bath of molten salt (typically potassium nitrate) at about 450° C. In one preferred embodiment, the ions are sodium and potassium ions (approximately 30% larger than the sodium ions), and the molten salt bath is made of potassium nitrate. The potassium ions are larger than the sodium ions and therefore wedge into the gaps left by the smaller sodium ions when they migrate to the potassium nitrate solution. This replacement of ions causes the surface of the glass to be in a state of compression and the core in compensating tension. The surface compression of chemically strengthened glass may reach up to 690 MPa. Chemical toughening results in increased toughness compared with thermal toughening or tempering, and can be applied to thin glass objects of complex shape.

A more advanced two-stage process for making chemically strengthened glass first immerses the glass article in a sodium nitrate bath at 450° C., which enriches the surface with sodium ions. This leaves more sodium ions on the glass for the immersion in potassium nitrate to replace with potassium ions. In this way, the use of a sodium nitrate bath increases the potential for surface compression in the finished article.

Chemical strengthening results in a strengthening similar to toughened glass. However the process does not use extreme variations of temperature and therefore chemically strengthened glass has little or no bow or warp, optical distortion or strain pattern. This differs from tempered glass, in which thin pieces can be significantly bowed.

Another method of forming tough glass fuses three glass sheets together at an elevated temperature where the outside glass sheets have a lower thermal expansion coefficient than the center glass sheet. Thus during cooling the inner glass sheet shrinks more than the outer two sheets causing tension in the inner sheet and placing the outer sheets in compression.

If the compression in the outer glass sheets is high enough, then it will be very resistant to scratches and makes a very tough interactive surface for the display and input sensor.

The tough glass sheet could be transparent and the display could be behind the tough glass sheet. The display behind the glass could display its image through the tough glass and the tough glass could be used to protect the display. The tough glass sheet could be written on directly with a marker or could have an input sensor that writes to the display as the display is being interfaced with. If a reflective display is placed behind the tough glass plate, then the glass has to be transparent so the light can propagate through the glass sheet and get reflected back through the glass by the display. If a front projection system is to be used as the display, then it would be advantageous to use a white or reflective tough glass sheet. The white tough glass could be a glass ceramic (for example canasite glass ceramics developed by Corning Inc.) or a phase-separated glass, like a phase separated opal glass used as the white stripe in a thermometer tube (which could be ion exchanged).

The ultimate blackboard or whiteboard would use a combination of both clear and white reflective tough glass. A large energy efficient reflective bistable display could be placed behind the clear glass section, and a color video rate projection system could be operated in the reflective tough glass section. One potential solution for the reflective tough glass section is a phase-separated opal glass, similar to the white strip in a thermometer tube. The phase separated opal glass composition would have to be designed to be ion exchangeable in order to make it scratch resistant. The white glass could also be a glass ceramic like canisite (Corning Incorporated).

Not only would the tough glass sheet serve as a scratch resistant interface that could be written on with color markers but it would also serve as a medium for an electronic touch sensor. There are many different touch sensors that could be integrated with the tough glass plate: resistive, surface acoustic wave, capacitive, surface capacitance, projected capacitance, infrared, strain gauge, optical imaging, dispersive signal technology, acoustic pulse recognition, or coded LCD: bidirectional screen. Out of all of these different touch technologies, two of them are best suited for large durable touch screens: optical imaging and Projected Capacitive Touch (PCT).

Optical imaging is a relatively-modern development in touch screen technology. Optical imaging uses two or more image sensors placed around the edges (mostly the corners) of the screen. Infrared backlights are placed in the camera's field of view on the other sides of the screen. A touch shows up as a shadow and each pair of cameras can then be triangulated to locate the touch or even measure the size of the touching object or distance away from the touch surface. This touch technology is growing in popularity, due to its scalability, versatility, and affordability, especially for larger units. In order for the optical imaging touch system to be very sensitive to the exact moment when the surface is touched, the touched surface has to be very flat. Therefore, a flat tough glass plate touch surface works very well with this optical imaging sensor.

Projected Capacitive Touch (PCT) technology is a capacitive technology which permits more accurate and flexible operation by sensing the capacitive change in an XY grid or conductors. Applying voltages to the XY array or conductors creates a grid of capacitors. Bringing a finger or conductive stylus close to the surface of the sensor changes the local electrostatic field. The capacitance change at every individual point on the grid can be measured to accurately determine the touch location. The use of a grid permits high resolution and also allows multi-touch operation. A PCT sensor allows for operation without direct contact, such that the XY conducting grid can be placed behind the tough glass plate. Since it senses a capacitive change, it is beneficial to keep the tough glass sheet as thin as possible and as uniform in thickness as possible. Therefore, an ion exchanged fusion drawn glass plate would be the most desirable tough glass solution for a PCT sensor.

The eSheet technology can be used to manufacture very large, energy-efficient LCD panels at a very low cost. The eSheet technology can also be used to make a projected capacitive touch sensor. Therefore, sandwiching the thin, light weight tough glass, the eSheet projective capacitive touch sensor and the energy-efficient reflective eSheet LCD creates the best solution for the next generation electronic blackboards for schools around the world.

### Keyboard and Computer

One method of making a keyboard makes a multi-scan line (about 6) Ch. LCD panel that is pressure sensitive. Then each of the lines (the whole panel) can be written to the focal conical state. The panel could be “read” or the capacitance at each pixel could be measured. This could be done one line at a time (but very fast <<1 millisecond). If any pixel in the line is in the planar state, the location (letter or number) could be documented and the line could be rewritten to the focal conic state by simply applying an AC voltage past V₂ in the bathtub curve discussed in FIG. 3. The lines in the keyboard could be continuously sensed, logged and rewritten to the focal conical state (if needed). When the user types on the keyboard they will press on the panel and create a phase change in the cholesteric LC from a focal conic state to a planar state. The change creates a large change in the index of refraction, leading to a change in dielectric constant leading to a change in the capacitance. The change in capacitance can be sensed and equated to the character at the location that has been pressed and deformed. The shift or cap locks could have a small LED on the panel that lights up when pressed. The speed of the keyboard is limited to the speed that the Ch. LC material can be written back to the focal conical state once deformed to the planar state, which at most should only be a couple of milliseconds.

This keyboard could be very thin and could pull out of a tablet PC. In addition, a Ch. LCD could be placed on the opposite side of the keyboard. This panel could serve as a message or a doodle board. A clear plate (glass or plastic) could be placed on the back of the PC such that when the keyboard is docked inside the PC the message board can be read through the glass. Likewise if the resolution of the message board is high enough, then it can serve as a static energy-efficient display. The most popular use of a static display in this form factor is an electronic book. If the clear plate on the back is not there, then the message board can be directly interacted with on the back of the PC.

### Voting Machine eSheet Ch. LCD

A voting machine could use the pressure sensitive touch feature integrated into the Ch. LCD. The voting machine could be written to the focal conical state in the box area where the voter needs to touch to vote. The names of the candidates could be written with an area before or after the candidates to be pressed. The sensor could wait for the area in the box to be pressed. The pressed area could be sensed and the box could be rewritten with an X or [symbol] in the box. In addition the name of the person that was just voted for could be underlined or inverted (black on white) and the NEXT key in the bottom right could change to be highlighted (inverted, outlined or underlined). After the 1^{st} page of voting the BACK button could show up on the bottom left and a REVOTE button could show up in the bottom center. The name of the candidate and NEXT button could be changed without affecting the box that was pressed if the scan lines go across the name and the data lines run top to bottom.

### Interactive Board

The advent of the ability to electronically write to the display, physically (pressure sensitive) write on the display and then read what has been written on the display at the end using virtually no power opens up a large range of interactive boards. There are several markets for these types of displays. One of the largest markets that require very large displays are interactive school blackboards. These electronic blackboards differ from that discussed above in that the surface is not covered (protected) using a glass plate, but is exposed to the students and teacher. Programs can be written for the interactive display to do many different problems. For instance, a math question could be electronically written to the display and the student has to solve and write the answer. The display can be scanned and the answer can be run through an OCR converter. If the student gets the question correct, then correct can be written next to the answer. There are many times that the teacher needs to draw onto the chalkboard and annotate the drawings. This type of interactive display allows the teacher to electronically write the drawing and annotate it. The notes on the board can be electronically read and sent to the teacher's main computer or wirelessly to all the students in the class. Therefore, the students can focus on what the teacher is teaching and interact with the teacher and not worry about taking notes. The notes from the eBlackboard are electronically supplied to the students.

Interactive boards can be placed almost anywhere. One interesting application is for an interactive board that can be used as a calendar or message board. The interactive board can be attached to a wall or on the front of a refrigerator. The interactive board could have a wireless link that would allow it to communicate with a computer, such as a smartphone. The smartphone could be used to wirelessly write images and information to the board and could also be used to receive information written onto the interactive board. One example would be using the interactive board as a calendar. The calendar with all the appointments for the day, week, month or year could be written to the interactive board. As appointments are scheduled, they could be added to the interactive board using the pressure sensitive LC writing ability. The interactive board could be scanned and the appointment could show up on the smartphone. Note that the interactive board requires so little power that it could be powered using a solar cell and a battery. This low-energy, self-contained, wireless unit could be placed almost anywhere.

### Emergency Vehicle Message Display

One interesting application for the eSheet LCD technology is a message display in an emergency or service vehicle. One space the eSheet LCD could be designed into without occupying any additional space is integrated into a light bar. In this light bar case, the display could be part of the siren and could flip up to display a message. Alternatively, the display could be part of the bottom of the light bar and the entire light bar could flip up and display a message similar to that discussed in U.S. Pat. No. 7,825,790 “Emergency Vehicle Light Bar with Message Display”, incorporated herein by reference. The eSheet LCD could be placed on the hood of the vehicle with the ability to flip up and display a message. In one embodiment, the vehicle is a dump truck. Since the display is on the bottom and is flipped up, it could be protected using a durable metal housing. The eSheet LCD could also be placed on the trunk of the vehicle and flipped up for viewing. The eSheet LCD could be placed on the back of the vehicle or the side of the vehicle. Placing the display on the side or back of the vehicle is very advantageous for a panel truck, delivery van or a trailer for a tractor trailer.

The eSheet LCD could be used as a message, an information display, or an advertising display. Using a cholesteric LC material creates a reflective eSheet LCD. The reflective eSheet cholesteric (Ch.) LCD could be backed with a transmissive LCD. The reflective eSheet LCD could be used during the day to display images and the transmissive LCD could be used at dark to display images. The transmissive LCD could be a passively addressed LCD where a liquid crystal is sandwiched between eSheet substrates. Polarizers would have to be placed on both sides of the transmissive eSheet LCD and the display would have to be backlit. A color filter could be patterned on one of the two eSheets to form a color transmissive LCD. Using a three-layered Ch. LCD stack and with the color transmissive LCD would form a full color display optimized for daytime and night viewing.

The reflective eSheet Ch. LCD could have an integrated wire-based LED as a nighttime display. LEDs can be attached to the wires in an X-Y eSheet grid (similar to FIG. 16). The wires can be used to passively drive the LEDs, which means that only one line of LEDs can be emitting at one time. To be able to matrix address the array of LEDs, each pixel “LED” has to have an associated driver. The LED driver for each pixel can be designed to drive more than one LED and can be designed to drive red, green and blue LEDs. The LED driver can also have shift registers, logic and latching circuitry to set the emissive state of each LED in the pixel driver chip. The pixel driver chips could be designed into the surfaces of a glass substrate and sliced into small individual chips. The pixel driver chip could have in an inset in the chip to recess the LEDs. Having low profile pixel driver chips would allow the chips to be embedded into the surface of a polymer sheet or plate to make the surface flat. The wire eSheet needs power ground and data lines to drive the pixel driver chips. The pixel driver chips have to be designed to be connected to the wires in the eSheet and the pixel driver chips have to be aligned and connected to the eSheet wires.

### Automotive Displays

There are two major areas in an automobile that are good fits for an eSheet touch panel: the center console and the dashboard. The center console would be one big piece of “light weight” Gorilla glass with an eSheet attached touch sensor. The Gorilla glass and eSheet touch sensor could have a slot for CDs for DVDs and input plugs like USB or music jacks. Displays (LCDs, VFD, LEDs, etc) and indicators like LEDs or LCDs could also be integrated behind the eSheet sensor. All of the HVAC, CD, DVD and other inputs could be sensed using the eSheet capacitive touch sensor. The surface of the console could have printed buttons with the eSheet sensor behind them. The wires in the touch sensor could be at different pitches in the touch sensor to accommodate the different interactive areas. The wires could be on a larger pitch under the “single button” inputs (such as stereo and HVAC inputs) and a finer pitch above the main input display.

The dashboard, the other sensor/display place in a car, could have all the speed, odometer, voltage for battery, temperature sensor, etc. with the touch interactive sensor behind it. One interesting feature would be to touch the “gauge” and it would show up on the center consoles display or in a heads-up display or it could page through multiple screens like is presently done in most odometers.

### Appliances

Appliances in the home like stoves/ovens, refrigerator, dishwashers, compactors, washers and driers, etc could also use the eSheet touch sensor behind glass or scratch resistant plastic. One of the most interesting applications for appliances is the stove/oven console. In this case the inputs like temperature settings for the burners, oven, lights, timing/timers, etc. could all be behind one plate of glass or plastic (like Gorilla glass) with an eSheet touch sensor on the back side. There could also be a display for time and LEDs to show settings or hot surfaces.

The eSheet wires could be attached to the molded or shaped glass or plastic surface. The eSheets could also be attached directly with contact adhesive or thermal adhesive. The eSheets could also be attached using silicone, or even the eSheet “substrate” that holds the wires could be made out of silicone.

The eSheet wires could be the standard coated magnetic wire (i.e. multilayer coated copper wire) or, if the eSheet sensor needs to survive higher temperatures, like may be required for stoves/ovens, it could be composed of silicone coated wire and may be even backed or attached to the glass with a silicone material.

The eSheet touch panel is composed of a crisscrossing wire grid, where the wires are coated with some organic or inorganic material so they can be crisscrossed without shorting. It is preferred that the wires are made out of a soft (low-cost) material so they can bend around each other and be in the same plane. Copper with a polymer or silicone coating is a very good choice because of its high conductivity and low-cost. Using “freestanding” wires to create the eSheet touch sensor allows for easy connection to the printed circuit board and allows for the wires to be bent at any angle, zigzagged or woven across the eSheet in any shape. The wires can be held to any substrate (glass, polymer, silicone, metal, wood, ceramic, or combinations there of like projector screen, white-board, smart-board, etc.).

In order to hold the XY eSheet grid together when being applied or attached to a substrate (glass, plastic, Gorilla, wood, projector screen, etc.), the place where the XY isolated (shielded) wires cross may need to be attached to keep the pitch and alignment of the wires constant or under control. The wires could also be woven to hold the pitch.

### Other eSheet LCD Products

The eSheet LCD technology provides for low cost fabrication of many different large size LCDs for many different markets. One potential market is an outdoor changeable copy board. These roadside changeable copy boards traditionally are 4′×8′. The changeable copy board can have solar cells and batteries to power them and can have a wireless link like WiFi, WiMax or 3G/4G to update them. Having both self contained power and a wireless communication link allows these displays to be installed in almost any outdoor application, including roadside message boards and pole-based displays. One key application is to have an electronic movie marquee that displays what movies are playing inside the movie theater. The movie letter boards are traditionally very high up in the air and have safety issues changing the letters. An eSheet LCD would be a perfect fit for these large size letter boards.

Another application for the eSheet LCDs is at airports. There are several applications that use static signs in airports where flight information is updated. One application is for the arrival and departure displays through out the airport. These displays need to be updated on a regular basis, however only show static information. Another location is the large displays behind the terminal counters providing information about the flights at that specific gate. Also, the display at the terminal door could be a reflective eSheet LCD tied to the main computer system. One low power display opportunity in airports is on the luggage carts. The luggage cart display could depict which gate the luggage on the cart belongs to. Also, any misplaced bags could be sensed and displayed as not belonging to the gate. A wireless tag could be integrated into the luggage tags and communicate to the luggage cart display system. A low power display would allow the display and luggage tracking system to run off of solar cell and battery power.

The traffic sector has many potential applications for a large low power display. One application is the traffic signs above the roads and highway. A reflective display replacement for the portable signs on trailers would provide a low power solution with much better daytime viewing than the traditional trailer displays. Reflective eSheet LCDs could be integrated into road barriers, both concrete and water-filled barriers. They could be attached to vehicles, such as panel trucks and tractor trailers, and serve as moving billboards.

Besides electronic blackboards, there are many different applications for reflective, energy-efficient, eSheet LCDs in schools. One is a display outside of lecture halls and conference rooms showing what classes are scheduled in that room for the day. In one preferred embodiment, these displays are solar cell-powered with wireless links that would allow them to be installed without a power outlet. Standalone signs providing information about the day could also be used through out the schools. These last two display applications also exist in many different environments like restaurants, hotels, hospitals and corporations.

Distribution centers also count on displays to instruct them where to load different freight. Lots of different shipping merchandise is coming with RF ID tags that can be read with a wireless system and the contents and location of which trucks can be displayed on a screen. The large reflective eSheet LCDs would be perfect screens for these applications.

One application that has always received a lot of press is pricing rails in supermarkets. One problem with these applications is making a display with very long addressing lines, i.e. a 2″×840 display. The display needs to be addressed in the 8′ direction, which is difficult using most existing addressing substrates. The eSheet addressing substrate is a perfect fit for this application. Its conductive electrodes are able to reliably address these long lengths. For the short data directions a glass substrate with patterned ITO could be used. Therefore, in such applications, a half eSheet half glass/ITO based LCD could be used.

Gas stations around the country are starting to adopt electronic pricing signs. The eSheet LCD technology would be a good fit for these applications. One dual function display is a reflective cholesteric LCD over a passively address STN (standard twisted nematic) LCD. The panel structure for both of these displays could be fabricated using eSheets. Therefore, during the day the reflective LCD can be used and at night the reflective LCD could be placed in a transmissive mode and the transmissive LCD could be used. Likewise, an emissive LED display could be placed over or under the reflective display for night time viewing. These displays could be used for the large pricing signs found on poles near the gas station or on top of or nearby the pumps to show the price of the multiple grades.

These large eSheet LCDs could also serve as general advertising displays for both indoor and outdoor applications. Advertising displays have grown significantly in market size over the last several years as a result of lower cost plasma and LCD displays. The eSheet technology could extend these applications to both energy-efficient application and much larger sizes. The eSheet LCDs would also have a much lower cost in the really large sizes. The ultimate large advertising display is an electronic billboard. Electronic billboards are presently served using LED. A couple of companies are attempting to tile small glass-based Ch. LCDs, however they are fighting with the tiling seams and variations in panel to panel non-uniformities. Large single panel eSheet LCDs solves the tiling issues and the conductive addressing lines provides uniform addressing characteristics across the display.

Tabletops provide another large potential market application. Being able to interface with a display on the tabletop in a restaurant provides many advantages. First, the menu could be display and read on the tabletop. Orders could be entered, as well as service requests (please fill my drink, extra napkin, etc.), and would change the service in the restaurant. The tabletop could be used to surf the web, read the paper or play games. The tabletop could also be used as an advertising space. There are many different applications for tabletop displays outside of the restaurant, such as homes, school desks, work desks and military maps.

Another application for the eSheet LCDs is camouflage for the military. The military is always interested in being able to hide or cloak their equipment from satellite view. Large eSheet LCDs could be drooped over tanks, helicopters and airplanes and an image of the surroundings could be written on the display. The displays for these applications would not have to be perfect, however they would have to support color to be able to mimic there surroundings.

Another application for the eSheet LCD is wallpaper or ePaint. The eSheet LCD could be designed to cover the wall and virtually any image could be written on the wall, including color shades, patterns and even images like artwork, portraits or pictures. Likewise, the eSheet LCDs could be incorporated into the floor where virtually any image could be written to it. The eSheet LCD could encompass the entire floor or the eSheet LCD could surface as an electronic rug (eRug). The eRug could have many different applications especially if it was not protected with a stiff glass or plastic plate. If the surface of the eSheet LCD was exposed, then the eRug would be pressure sensitive. The eRug could serve as a doodle rug for the kids to play and draw on. As one walked across it, they would leave footprints. An image or logo could also be printed on the back of the eRug and it could be placed in the lobby of a company. As a visitor approached the desk, they would walk over it leaving their footprints behind. The footprints (and any other marks) could be electronically cleared.

### Projection Display eSheet Touch Sensor

One of the easiest applications for the eSheet technology is a touch sensor designed into a projection screen. The most simple touch sensor is a projected capacitive touch sensor. The eSheet wire grid is attached to the back of a standard projector screen. If the horizontal wires in the touch sensor, preferable the scan lines, are turned to a 90 degree angle at the edge and extended up to the top of the panel where they connect to the electronic, then the display is rollable. Having a rollable display allows the projector screen to be pulled up and down like a standard projector screen. The electronics are preferably housed inside the center of the rolled screen/sensor. The touch sensor could also be wired or wirelessly tied to the projector or computer that drives the projector. The eSheet touch sensor could be fabricated in a separate substrate and attached to the projector screen or could be build directly on the backside of the projector screen.

### eSheet Plasma Sphere/Puck Display

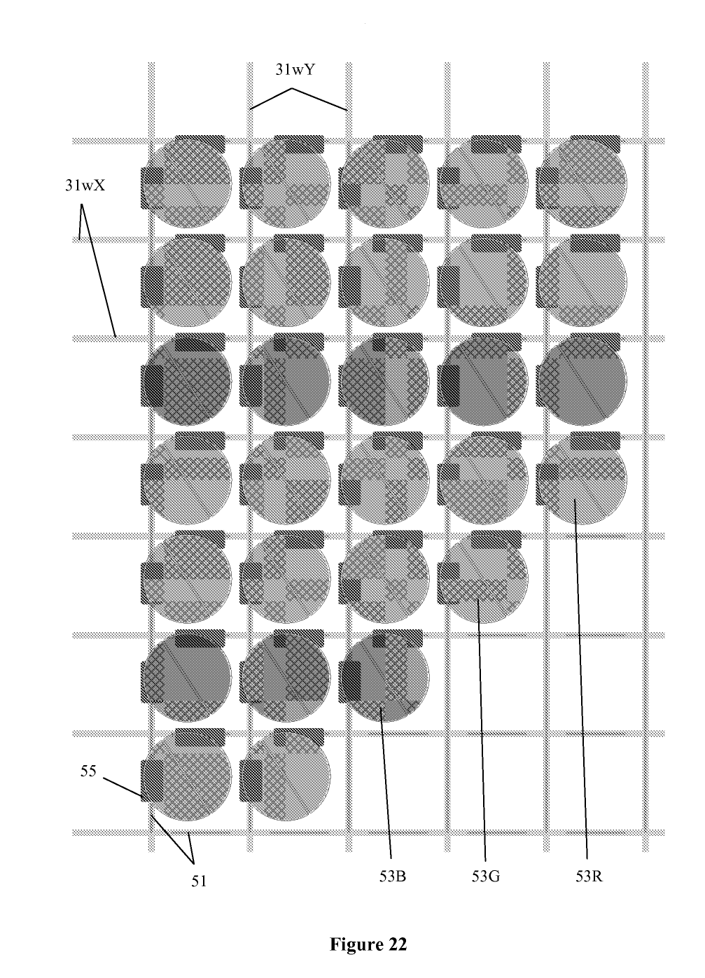

FIG. 22 shows an example of how the eSheet can be used as an addressing substrate for plasma spheres or plasma pucks. The grey lines 31wX and 31wY are the wires and the orange areas 51 are where the wires are exposed to the surface. Small glass filled volumes 53 called plasma spheres or “plasma pucks” can be coated with red 53R, green 53G, and blue 53B phosphor coatings on the outside or inside and filled with a gas capable of igniting a plasma can be used as point emitters. The plasma spheres 53 will have to have at least two metal contacts on the surface of the plasma sphere 53 to create a uniform electric field inside the plasma sphere to uniformly ignite the plasma. The plasma spheres 53, or “plasma pucks” (red 53R, green 53G, and blue 53B), are rotated to about 45 degrees and attached to the exposed wire electrodes 31wX and 31wY such that the bottom electrode contacts cross both exposed lines. Conductive contact adhesive (purple 55) can make the electrical connections between the exposed wire 51 and the plasma pucks 53. Simple X-Y addressing and sustaining using the wire electrodes 31wX and 31wY can be used to light the plasma pucks 53 up and create an image on the eSheet plasma sphere display.

There are many different eSheet electrode configurations that can be used as a support substrate for the plasma spheres or plasma pucks. Two, three and four electrodes per plasma puck can be used to address the plasma spheres. Using multiple electrodes allows the sustain and data electrodes to be separated. The plasma spheres can also be tied together using free standing wires. The plasma spheres and the wires can then be potted in a silicone or polymer film.

In another embodiment, the plasma pucks 53 could be replaced with LEDs. By connecting the two contacts of an LEDs at each crisscrossing the wire electrodes 31wX and 31wY, a passively addressed LED-based eSheet display can be formed.

### eSheet Products

There are many potential uses for an electroded sheet (eSheet). An eSheet can supply power to a line or plane in a device, such as a display, eSign, lamp, touch screen, battery, printer, speaker, heater, sensor, ribbon cable, or transmitter to name a few. An eSheet can also remove power from a line or plane in a device, such as a solar cell, fuel cell, battery, EMF/EMI shielding, sensor, or antenna to name a few.

### eSheet Display Products

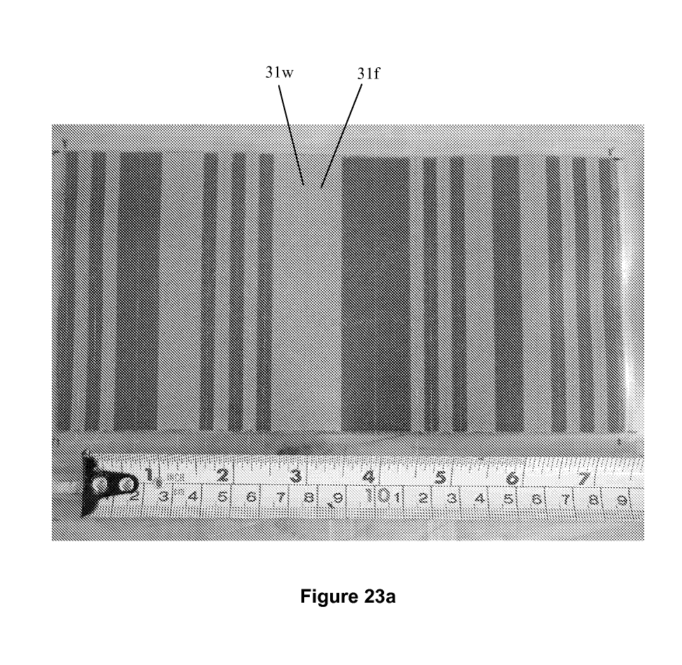

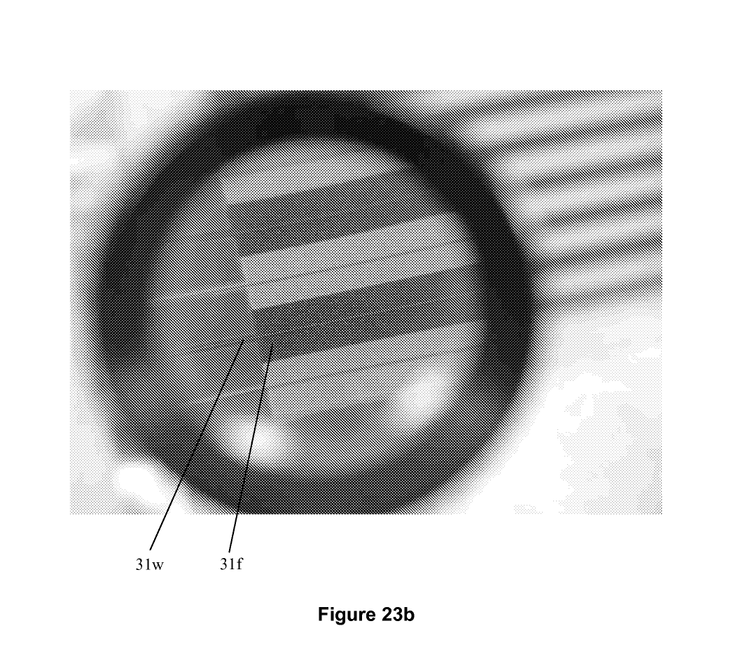

An electroded sheet or eSheet can be used for a vast number of different display products. The first type of display product using an eSheet is a segment addressed display. A segment addressed display means that each segment in the panel is attached to its own driver. The most simple segment addressed panel structure is two eSheets sandwiched around an electro-optic material, such as a liquid crystal (LC), electrophoretic, gyricon, electrochromic, quantum dot or an organic light emitting diode (OLED) material. If at least one of the eSheets has a segmented pattern designed into the surface, then each individual segment can be switched by applying a potential to that segment in the eSheet. FIG. 23 shows two examples of electro-optic materials being modulated while sandwiched between two eSheets. FIG. 23a shows a Gyricon electro-optic material sandwiched between two electroded sheets (eSheets) where the top eSheet has a varying electrode pitch of 0.1″ to 1″. The top wire electrodes 31w in the eSheet are interdigitated and the voltages on each set of interdigitated pairs are switched to the two separate addressing voltages. The sample demonstrates that the voltage can be spread from a single electrode 31w across ½″ of the transparent conductive electrode 31f to modulate the electro-optic material. FIG. 23b is a 10× zoomed in image of an eSheet switching E-Ink's electrophoretic material. The electrophoretic material switches under the wire electrodes 31w, but only close to the wire electrode unless the transparent conductive coating 31f is applied to the bottom of the eSheet. Note that in both images in FIG. 23, the transparent conductive electrode 31f was only applied and patterned where the electro-optic materials are switched between the black and white states. The eSheet may also be combined with plasma tubes to create a segment addressed display. Applying an AC between the eSheet electrode and an electrode in/on the plasma tube ignites a plasma inside the plasma tube. Another type of display product using an eSheet is a passive addressed display.

A passive display usually has an x-y grid of electrodes where voltages can be applied to the individual electrodes to generate an image in the display. Addressing a passive display requires that the image is written to the display one line at a time and the electro-optic material has a voltage threshold. The voltage threshold requirement means that the difference in the voltage to switch the display between its two states has to be less than the switching voltage of the electro-optic material. An image can be generated in an electro-optic material by sandwiching the electro-optic material between two patterned striped eSheets and applying the proper voltage waveforms to the wire electrodes in the eSheets. The most well known electro-optic material that has a threshold and can be passively addressed is a liquid crystal (LC). If a standard twisted nematic LC is used, then polarizers have to be added to the passively-addressed display. There are other types of LC materials with voltage thresholds, like cholesteric LC and smectic A LC, that do not require polarizers and are also reflective and bistable. Reflectivity is very important for low energy applications because they do not require backlights. Bistability means that when an electro-optic material is modulated to a different state, it holds that state until it is forced back to its original state, where multistable means the electro-optic material has many stable states. These reflective bistable color displays may replace standard color prints. There are two methods of creating a reflective color display or electronic sign (eSign). One method places the red, green and blue (RGB) pixels side-by-side like is presently done in all color video displays. A second method stacks the red, green and blue pixels on top of each other. This stacking method requires that the electro-optic material may be modulated from a transparent state to a reflective red, green or blue state. This stacking method also allows for the usage of the entire pixel to reflect the entire visible spectrum. In contrast, when the RGB colors are placed side-by-side, ⅔ of the light is wasted because the red pixel does not reflect green or blue, and a similar phenomenon occurs for the green and blue pixels. Therefore, a RGB stack three layer panel is required to create a high quality reflective color display. There are two known materials that may be modulated from a transparent to a reflective R/G/B state, a cholesteric liquid crystal (developed by Kent Displays) and a smectic-A liquid crystal (developed by PolyDisplay/TechnoDisplay). Both of these liquid crystals have thresholds and may be passively addressed. Therefore, reflective color electronic signs may be fabricated by using three separate panels consisting of two orthogonal electroded sheets sandwiched between each of the three color liquid crystal materials. This Stacked eSheet eSign (SeS) allows for the manufacture of very large single substrate electronic signs (eSigns). A reflective color electronic sign may also be formed using two single-sided electroded sheets sandwiching two double-sided electroded sheets with the three primary color liquid crystals layers between each electroded sheet. Note that if the display is reflective, then it would be advantageous to use cyan, magenta and yellow instead of red, green and blue for the colored liquid crystal materials. There are also other passively-addressed displays that may be constructed using electroded sheets. If an electroded sheet is designed such that the electrodes are exposed to the surface, then they may be used to address electro-optic materials that require current such as, electrochromic displays and passive addressed organic light emitting diode (OLED) displays. The electroded sheet may also be used to address other electroluminescent materials, such as quantum dots (as being developed by QD Vision, MIT's QD-OLED, and Evident Technologies). Passively-addressed displays are good for non-video rate applications.

For video rate applications, such as TV, a display with active addressing is required. An actively-addressed display is one that uses a switch “at every pixel” to set charge or flow current onto that pixel. Some examples of active switches used in displays are transistors, diodes, plasmas and microelectromechanical (MEMS) elements. The actively-addressed displays are traditionally addressed one line at a time; however, it is the active switch, like a transistor, that is being addressed and not the electro-optic material. Active switches, like transistors, can be modulated much faster than most electro-optic materials; therefore the charge can be set very quickly at each pixel and the electro-optic material can then respond to that set charge. Adding an active switch to the displays removes the requirement that the electro-optic material has threshold. The most well know and widely used active display is the active matrix liquid crystal display (AMLCD), which used a transistor at each pixel in the display to charge a pixel pad, in turn modulating the LC at that pixel. An electroded sheet may alternatively be used as the column addressing plane in a plasma-addressed electro-optic display (PA-EO). In this case, the electroded sheet serves to set the charge in the plasma channels and act as a ground plane for modulation of the electro-optic material. The plated out charge in the plasma channels creates an electric field, which may be used to address several different electro-optic materials: liquid crystals, twisting balls or twisting cylinders (like those being developed by Xerox “Gyricon”), electrophoretic materials (like those being developed by E-Ink or SiPix), or suspended particle devices (such as those being developed by Research Frontiers Incorporated).

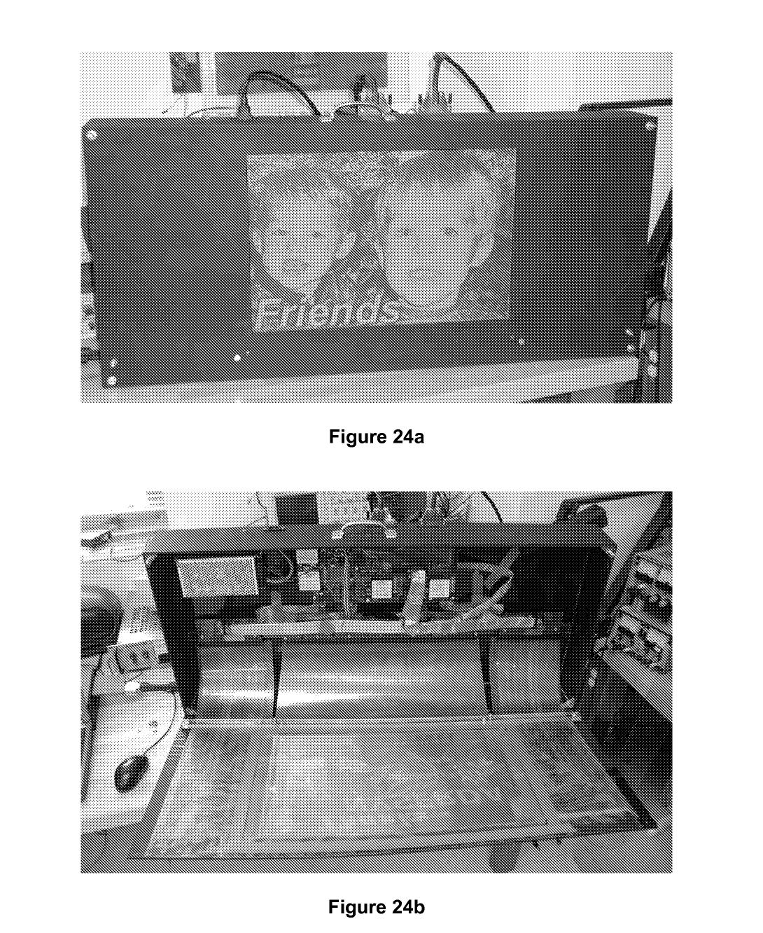

FIG. 24A shows a plasma-addressed display using Gyricon ePaper as the electro-optic material. An eSheet is used for the column addressing plane in the display and an array of plasma tube is used to generate and store the charge. The Gyricon ePaper is sandwiched between the eSheet and the plasma tube array. The display in FIG. 24A has 384 pixels×255 pixels and is 23 inches diagonal. FIG. 24b shows the display opened up and that all the wire electrodes are connected to a circuit board on one edge of the displays. The wires from the plasma tubes are bent to a 90° angle to connect to the electronics. Another type of active display is a plasma display. A plasma display can be fabricated using an electroded sheet attached to an array of plasma tubes as explained in US Patent Publication US2007/0132387, filed Dec. 11, 2006, entitled “TUBULAR PLASMA DISPLAY” and PCT Patent Application Number PCT/US2006/061872, filed Dec. 11, 2006, entitled “WIRE-BASED FLAT PANEL DISPLAYS”, both incorporated herein by reference.

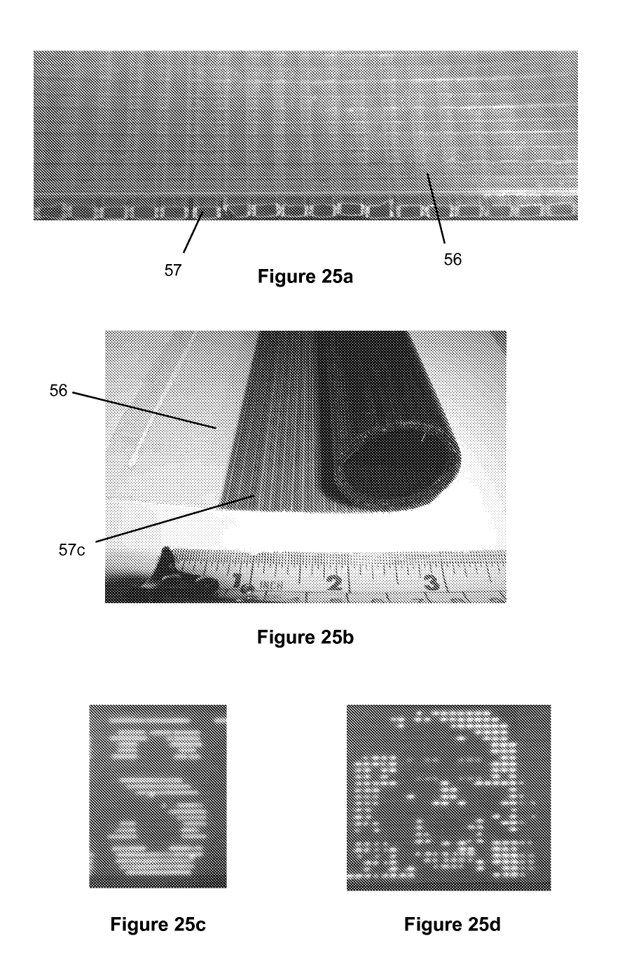

FIG. 25a shows the basic structure of a tubular plasma display panel where an array of plasma tubes 57 is attached to an eSheet 56. FIG. 25b shows another basic property of an eSheet display. Since the eSheets are formed on a flexible substrate, they can be rolled up. FIG. 25b shows an array of color coated plasma tubes 57c attached to an eSheet 56 that is rolled up into a tube. Therefore, it is possible to make a rollable color video display. FIGS. 25c and 25d show images of a tubular plasma display where alternating tubes are coated with color phosphors and sealed closed with a Xenon containing base gas. The images are actively addressed by applying voltage waveforms to the wire electrodes in the eSheet and the wire electrodes in the plasma tubes.

Some layers in flat panel displays require RGB color filters. In these cases, the color filter may be added to the electrode sheet. The RGB colors may be added to the TCE coating such that when they are deposited in a pattern, the color filter is deposited at the same time. In this case the RGB color filter is inherently aligned with the electrodes. The color filter may also be applied on top of the electroded sheets.

Most liquid crystal displays require polarizers in the optical film stack. Most traditional passive and active liquid crystal displays sandwich the liquid crystal cell with electrodes between two polarizers. The electroded structure could be designed into the surface of these polarizers, therefore the polarizer would serve as the substrate for the eSheet. The rubbing layer or liquid crystal alignment layer may also be applied to the surface of the eSheet polarizer. If the wire electrodes can not be embedded into the polarizer substrate, then an additional thermal polymer material can be applied to the surface of the polarizers and the wire electrodes can be embedded into the surface of the thermal polymer. Another method of creating an eSheet polarizer forms an eSheet in a separate process and substrate and optically bond the eSheet to the polarizer.

Electroded sheets could also be used for many other types of displays like microelectromechanical (MEMS) displays and 3-D and multi-view displays. 3-D and multi-view displays may require that a lenticular or other lens shape be embossed or molded into the surface of the electroded sheet while it is being formed.

The electroded sheets could also be used to form a display, like a reflective color electronic sign, as discussed above, and the electronic sign may be used in combination with another display, like a color video display. Combining more than one display serves multiple purposes, such as, a reflective electronic sign, color video, three-dimensional display, multiple view display and a double-sided display. Combining a reflective bistable color liquid crystal electronic sign with a color video display creates a display that optimally displays static images using the liquid crystal sign section without phosphor burn-in and large energy consumption and is also capable of creating full motion video. If a three layer color stacked liquid crystal display is formed using electroded sheets, and it is attached to a tubular plasma display formed using plasma tubes attached to an electroded sheet, then the combined display perfectly serves both static and video images and is rollable.

### Other eSheet Products

The eSheets and methods of forming the eSheets can be used to make many different other types of products. ESheets may be used to make solar cells, such aα-Si, CdTe, CdSe, CdS, CuInSe₂, dye-sensitized solar cells, organic/polymer solar cells, and nanostructured photovoltaic devices, to mention a few. The eSheets can be used to make single solar cells or the pattern eSheets can be used to make a series of solar cells, where several solar cell devices are tied in series for higher voltages. Since most versions of the electrode sheet use a transparent conductive electrode, it is beneficial for the eSheets to be used for the top electrode plane. The top surface of the eSheet may also be textured to couple more light into the solar cell.

ESheets may be used to fabricate electrochemical cells, such as fuel cells and batteries. Fuel cells may also be constructed using eSheets; however it is not necessary for the transparent conductive electrode, which is attached to the wire electrode, to be transparent. The conductive coating connected to the wire electrodes for each side of the cell may be the anode and cathode of the fuel cell, which sandwiches the electrolyte (or proton-conducting polymer membrane) in a proton exchange membrane fuel cell. The anode in the eSheet may contain platinum or platinum alloy to separate out the hydrogen and deliver it to the electrolyte. The eSheet substrate may have grooves or channels on the surface to deliver the gases to the cell. The eSheet substrate material may also be porous to allow the reactive gases to flow into the cell. The wire electrodes in the fuel cell are beneficial to be able to pull the current out of the cell with minimal loss in power. In addition, the wire electrodes can be composed of virtually any metal capable of being drawn into wire. Batteries may also be fabricated using electroded sheets where two eSheets may form the positive and negative electrodes and sandwich an electrolyte material. The wire electrodes can be used to discharge or charge the battery.

A preferred use of the eSheet in a large area sensor is for touch screens using a resistive, capacitive and projective capacitive sensors. A multiplexed touch screen sensor can be built using an x-y grid from two orthogonal eSheets. The wire electrodes can be attached to the electronics to send and sense the location of the disturbance along the length of the line. The wire electrodes are very conductive and cause minimal dampening of the signal along the line. The transparent conductive stripes create a larger sensing area leading to higher sensitivity in the touch panel while blocking minimal light through the panel.

Electroded sheets can also be used to shield electromagnetic fields or EMI/EMF. The wire electrodes create an easy connection, and if a thin eSheet substrate is used then the EMF shield will be very formable or drapable. One difference in an EMF shield is that the transparent conductive electrode may not need to be patterned into stripes. Also, the conductive film attached to the wire electrodes may not need to be transparent.

The electroded sheet can also be used as an antenna to transmit or receive a wireless signal. The wire electrodes can be tied together at the ends to form a long antenna path through the eSheet. Also the eSheets can be made in very large or long sizes and can be rolled and unrolled for better reception.

Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

What is claimed is:

1. An electronic display component comprising at least two crisscrossing wire arrays on a substrate, wherein the wires in the at least two crisscrossing wire arrays are electrically isolated from each other.

2. The electronic display component of claim 1, further comprising a plurality of transparent conductive electrodes electrically connected to the wires in the crisscrossing wire arrays.

3. The electronic display component of claim 1, wherein the wires in the at least two crisscrossing wire arrays are connected to electronics on at least one edge of the electronic display component.

4. The electronic display component of claim 1, wherein the crisscrossing wire arrays are used as a projected capacitive touch sensor.

5. The electronic display component of claim 4, wherein the projected capacitive touch sensor is used in a product selected from the group consisting of:
a) an electronic whiteboard;
b) an electronic blackboard;
c) a smartboard;
d) a projection display;
e) a plasma display;
f) an LCD;
g) an OLED;
h) an information display;
i) an advertising display;
j) an interactive display;
k) a voting machine;
l) a three dimensional display;
m) a multiple view display;
n) a flexible display;
o) a rollable display;
p) curved display, and
q) any combination of a) through p).

6. The electronic display component of claim 4, wherein the projected capacitive touch sensor further comprises a wireless communication link between the touch sensor and a second device.

7. The electronic display component of claim 4, further comprising a tough glass interface.

8. The electronic display component of claim 1, wherein at least one wire in the at least two crisscrossing wire arrays is a coated copper wire.

9. The electronic display component of claim 8, wherein the coated copper wire comprises a coating and at least part of the coating is removed to expose the wire to a surface of the substrate.

10. The electronic display component of claim 9, wherein at least part of the wire is coated with an electrically conductive material.

11. The electronic display component of claim 1, wherein the at least two crisscrossing wire arrays comprise a first wire array comprising a first plurality of wires and a second wire array comprising a second plurality of wires, wherein the first plurality of wires bend around the second plurality of wires such that a majority of the first plurality of wires and the second plurality of wires are in a same plane.

12. The electronic display component of claim 1, wherein the wires in the crisscrossing wire arrays are electrically attached to at least one plasma sphere or plasma puck.

13. A method of writing on an eSheet cholesteric liquid crystal display using a solid object, comprising the step of deforming a liquid crystal region and creating a phase change from a focal conical texture to a planar texture.

14. The method of claim 13, wherein the eSheet cholesteric liquid crystal display comprises a thin glass sheet on an input surface.

15. The method of claim 13, further comprising the step of sensing a phase change by measuring a change in pixel or line capacitance using a plurality of wires in the eSheets.

16. The method of claim 15, wherein the method is used in product selected from the group consisting of:
a) an electronic whiteboard;
b) an electronic blackboard;
c) a smartboard;
d) an information display;
e) an advertising display;
f) an interactive display;
g) a voting machine;
h) a three dimensional display;
i) a multiple view display;
j) a flexible display;
k) a rollable display;
l) curved display, and
m) any combination of a) through l).

17. An electroded sheet comprising:
a) a polymer substrate wherein a width and a length of the polymer substrate covers substantially a width and a length of the electroded sheet; and
b) an array of wire electrodes embedded in a surface of the polymer substrate;
wherein each wire electrode is a highly conductive thread-like or fiber-like material;
wherein the wire electrodes are formed using a standard wire forming process as free standing entities, are not evaporated or deposited on the substrate and are capable of being extended away from the substrate and connected directly to a printed circuit board; and
wherein the electrodes perform a function selected from the group consisting of:
A) applying power to the device;
B) removing power from the device; and
C) a combination of A) and B).

18. The electroded sheet of claim 17, wherein the electroded sheet forms at least a portion of a device selected from the group consisting of:
i) a flat panel display;
ii) a solar cell;
iii) a fuel cell;
iv) a battery;
v) a resistive touch screen;
vi) a capacitive touch screen;
vii) a projective capacitive touch screen;
viii) a EMI/EMF shield; and
ix) an antenna.

19. The electroded sheet of claim 17, further comprising a polarizer added to the electroded sheet wherein the polarizer is added to the electroded sheet using a method selected from the group consisting of:
a) forming the electroded sheet directly into a surface of the polarizer;
b) coating the surface of the polarizer with a thermal polymer and forming the electroded sheet in the thermal polymer;
c) forming the electroded sheet and attaching it to at least one surface of the polarizer; and
d) any combination of a) through c).

20. The electroded sheet of claim 17, further comprising additional surface structure on the electroded sheet selected from the group consisting of:
a) a lens array;
b) a stimpled antiglare surface;
c) a liquid crystal alignment layer;
d) a liquid crystal anchoring layer;
e) at least one channel for gas or liquid; and
f) any combination of a) through e).
